(19) United States
(12) Patent Application Publication
(10) Pub. No.: US 2025/0063901 A1
(43) Pub. Date: Feb. 20, 2025

(54) DISPLAY APPARATUS AND METHOD OF MANUFACTURING THE SAME

(71) Applicant: Samsung Display Co., Ltd., Yongin-Si (KR)

(72) Inventors: Yeongho Kim, Yongin-si (KR); Youngsoo No, Yongin-si (KR); Sungtae Hwang, Yongin-si (KR); Seonbeom Ji, Yongin-si (KR); Mingwan Kim, Yongin-si (KR)

(21) Appl. No.: 18/739,373

(22) Filed: Jun. 11, 2024

(30) Foreign Application Priority Data
Aug. 16, 2023 (KR) 10-2023-0107075
Apr. 23, 2024 (KR) 10-2024-0054277

(51) Int. Cl. H10K 59/126; G06F 3/041; H10K 59/12; H10K 59/35

(52) U.S. Cl. CPC H10K 59/126; H10K 59/1201; G06F 3/0412; H10K 59/351

(57) ABSTRACT

A method of manufacturing a display apparatus includes preparing a substrate including a first area in which a display layer including a plurality of light-emitting devices is located and a second area surrounding the first area, and forming an optical functional layer on the display layer, the optical functional layer including a light transmitting portion at least partially overlapping the plurality of light-emitting devices, a light blocking portion at least partially surrounding the light transmitting portion, an alignment mark formed through the light blocking portion, the alignment mark being disposed adjacent to a boundary between the first area and the second area, and a groove extending along the boundary between the first area and the second area.

### CROSS-REFERENCE TO RELATED APPLICATION

This application is based on and claims priority under 35 U.S.C. § 119 to Korean Patent Application No. 10-2023-0107075, filed on Aug. 16, 2023, and 10-2024-0054277, filed on Apr. 23, 2024, in the Korean Intellectual Property Office, the disclosures of which are incorporated by reference herein in their entirety.

### BACKGROUND

### 1. Field

One or more embodiments relate to a display apparatus and a method of manufacturing the same, and more particularly, to a display apparatus including a structure for preventing an alignment mark from being covered by fumes formed during cutting (or scribing), and a method of manufacturing the display apparatus.

### 2. Description of the Related Art

Display apparatuses visually display data. Display apparatuses are used as displays for small products such as mobile phones or are used as displays for large products such as televisions. A display apparatus includes a plurality of pixels that emit light in response to an electrical signal to display an image to the outside. Each pixel includes a display device. For example, an organic light-emitting display apparatus includes an organic light-emitting diode (OLED) as a display device.

To manufacture a display apparatus, a plurality of layers may be stacked on a substrate and then may be cut into a certain shape through a cutting process. The cutting process may use a laser. In order to cut the plurality of layers into a desired shape, an alignment mark for guiding lasers may be formed on one of the plurality of layers located on the substrate.

### SUMMARY

During laser cutting, fumes may be generated from some layers. Such fume particles may move along a bubble layer formed between layers located on a display apparatus to cover an alignment mark.

One or more embodiments include a display apparatus including a structure for preventing fumes from covering an alignment mark and a method of manufacturing the display apparatus. However, the embodiments are examples, and do not limit the scope of the disclosure.

Additional aspects will be set forth in part in the description which follows and, in part, will be apparent from the description, or may be learned by practice of the presented embodiments.

According to one or more embodiments, a method of manufacturing a display apparatus includes preparing a substrate including a first area in which a display layer including a plurality of light-emitting devices is located and a second area surrounding the first area, and forming an optical functional layer on the display layer, the optical functional layer including a light transmitting portion at least partially overlapping the plurality of light-emitting devices, a light blocking portion at least partially surrounding the light transmitting portion, an alignment mark formed through the light blocking portion, the alignment mark being disposed adjacent to a boundary between the first area and the second area, and a groove extending along the boundary between the first area and the second area.

The light blocking portion of the optical functional layer may include a light blocking layer, and the light transmitting portion of the optical functional layer may include a plurality of color filters located in a plurality of openings formed through the light blocking layer.

The optical functional layer may include a plurality of color filters which transmit light of different colors, and the light blocking portion may include at least two of the plurality of color filters overlapping each other.

The alignment mark may include a plurality of openings spaced apart from each other along one direction, and a shape of one of the plurality of openings is different from a shape of another one of the plurality of openings in a plan view.

The plurality of openings of the alignment mark may be formed through the optical functional layer.

The method may further include forming a reflective pattern at least partially overlapping the alignment mark.

The method may further include sequentially locating a first adhesive layer, an impact absorbing layer, and a second adhesive layer on the optical functional layer, and cutting the second adhesive layer, the impact absorbing layer, the first adhesive layer, the display layer, and the substrate along a scribe line disposed adjacent to the alignment mark of the optical functional layer.

A portion of the first adhesive layer may be located in the groove of the optical functional layer not to directly contact a layer disposed under the optical functional layer.

In the cutting, the scribe line may be disposed at the boundary between the first area and the second area.

A laser may be sequentially incident on the second adhesive layer, the impact absorbing layer, the first adhesive layer, the display layer, and the substrate.

The impact absorbing layer may be cut earlier than the second adhesive layer and the first adhesive layer during the cutting.

At least part of particles in fume generated during the cutting of the impact absorbing layer may move to the groove of the optical functional layer.

According to one or more embodiments, a display apparatus includes a substrate including a display area in which a plurality of light-emitting devices are located and a non-display area surrounding the display area, and an optical functional layer located on the substrate, the optical functional layer including a light transmitting portion at least partially overlapping the plurality of light-emitting devices, a light blocking portion at least partially surrounding the light transmitting portion, a stepped portion located at an edge of the non-display area, and an alignment mark located in the non-display area adjacent to the stepped portion.

The light blocking portion of the optical functional layer may include a light blocking layer and the light transmitting portion of the optical functional layer may include a plurality of color filters located in a plurality of openings formed through the light blocking layer.

The optical functional layer may include a plurality of color filters which transmit light of different colors, and the light blocking portion may include a portion where at least two of the plurality of color filters overlapping each other.

The alignment mark may include a plurality of openings located in the light blocking portion to be spaced apart from each other along one direction, wherein a shape of one of the plurality of openings is different from a shape of another one of the plurality of openings in a plan view.

The plurality of openings of the alignment mark may be formed through the optical functional layer.

The display apparatus may further include a reflective pattern at least partially overlapping the alignment mark.

The display apparatus may further include a first adhesive layer located on the optical functional layer while covering an edge of the optical functional layer disposed adjacent to the stepped portion, a part of the first adhesive layer being located to cover the stepped portion.

The display device may further include a touch layer disposed between the substrate and the optical functional layer. The first adhesive layer and the touch layer may not directly contact each other in the stepped portion.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating a mother substrate of a display apparatus according to an embodiment;

FIG. 2 is a cross-sectional view schematically illustrating a display apparatus, taken along a line II-II′ of FIG. 1 according to an embodiment;

FIG. 3 is an enlarged plan view illustrating a part of a mother substrate of a display apparatus, particularly illustrating a portion III of FIG. 1 according to an embodiment;

FIG. 4 is a cross-sectional view illustrating a part of a mother substrate of a display apparatus, taken along a line IV-IV′ of FIG. 3 according to an embodiment;

FIGS. 5A, 5B, 5C, 5D, 5E and 5F are cross-sectional views illustrating states in process steps of a method of manufacturing a display apparatus according to an embodiment;

FIGS. 6A, 6B, 6C, 6D and 6E are perspective views illustrating states in process steps of a method of manufacturing a display apparatus according to an embodiment;

FIG. 7 is a plan view illustrating states in process steps of a method of manufacturing a display apparatus according to an embodiment;

FIG. 8 is a plan view schematically illustrating a display apparatus manufactured by using a method of manufacturing a display apparatus according to an embodiment;

FIG. 9 is a cross-sectional view illustrating a part of a display apparatus manufactured by using a method of manufacturing a display apparatus according to an embodiment;

FIG. 10 is an enlarged perspective view illustrating a part of a display apparatus manufactured by using a method of manufacturing a display apparatus according to an embodiment;

FIG. 11 is an enlarged plan view illustrating a part of a mother substrate of a display apparatus, particularly illustrating the portion III of FIG. 1 according to an embodiment;

FIG. 12A is a cross-sectional view illustrating a part of a mother substrate of a display apparatus, taken along line XII-XII′ of FIG. 11 according to an embodiment;

FIG. 12B is a cross-sectional view illustrating a part of a mother substrate of a display apparatus, taken along line XII-XII′ of FIG. 11 according to another embodiment;

FIG. 13 is a plan view illustrating states in process steps of a method of manufacturing a display apparatus according to an embodiment;

FIG. 14 is a cross-sectional view illustrating a part of a display apparatus according to an embodiment;

FIG. 15 is an enlarged plan view illustrating a part of a mother substrate of a display apparatus, particularly illustrating the portion III of FIG. 1 according to an embodiment;

FIG. 16 is a cross-sectional view illustrating a part of a mother substrate of a display apparatus, taken along line XVI-XVI′ of FIG. 15 according to an embodiment;

FIG. 17 is a plan view illustrating states in process steps of a method of manufacturing a display apparatus according to an embodiment; and

FIG. 18 is a cross-sectional view illustrating a part of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Reference will now be made in detail to embodiments, examples of which are illustrated in the accompanying drawings, and in the drawings, the same elements are denoted by the same reference numerals, and thus a repeated description thereof will be omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

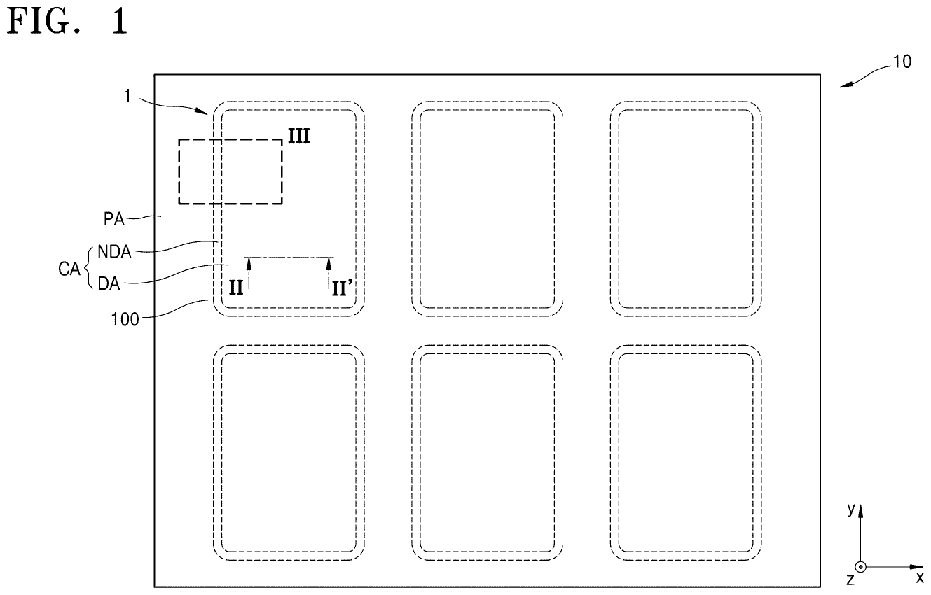

FIG. 1 is a plan view schematically illustrating a mother substrate of a display apparatus according to an embodiment.

Referring to FIG. 1, a mother substrate 10 of a display apparatus according to an embodiment may include a plurality of unit display apparatuses 1.

In an embodiment, the display apparatus 1 for displaying a moving image or a still image may be used as a display screen for not only a portable electronic device such as a mobile phone, a smartphone, a tablet personal (PC) computer, a mobile communication terminal, an electronic organizer, an electronic book, a portable multimedia player (PMP), a navigation device, or an ultra-mobile PC (UMPC) but also any of various products such as a television, a laptop computer, a monitor, a billboard, or an Internet of things (IoT) product.

Also, in an embodiment, the display apparatus 1 may be used for a wearable device such as a smart watch, a watch phone, a glasses-type display, or a head-mounted display (HMD). Also, in an embodiment, the display apparatus 1 may be used as a center information display (CID) located on an instrument panel, a center fascia, or a dashboard of a vehicle, a room mirror display replacing a side-view mirror of a vehicle, or a display located on the back of a front seat for entertainment for a person in a back seat of a vehicle.

The mother substrate 10 may include a first area CA and a second area PA. The first area CA may be a portion where elements of the display apparatus 1, for example, sub-pixels including light-emitting devices, are located. The second area PA may surround the first area CA. In a process of manufacturing the display apparatus 1, the mother substrate 10 may be cut along a scribe line which is a boundary between the first area CA and the second area PA. After the cutting, a portion of the mother substrate 10 corresponding to the second area PA may be removed. After the cutting, a portion of the mother substrate 10 corresponding to the first area CA, or the display apparatus 1, may be taken and moved to a subsequent process.

The first area CA may include a display area DA and a non-display area NDA outside the display area DA.

The display area DA is a portion where an image is displayed, and a plurality of sub-pixels may be located in the display area DA. Each sub-pixel may include a light-emitting device such as an organic light-emitting diode. Each sub-pixel may emit, for example, red light, green light, blue light, or white light. The display area DA may provide a certain image through light emitted from the sub-pixels.

The non-display area NDA where sub-pixels are not located may be a portion where an image is not provided. A signal lines connected to a driver integrated circuit (IC) or a printed circuit board including a driving circuit and a power supply wiring for driving the sub-pixels may be located in the non-display area NDA.

Although the first area CA and the display area DA have a substantially quadrangular shape with rounded corners in FIG. 1, the disclosure is not limited thereto. The first area CA and/or the display area DA may have any of various shapes such as a circular shape, an elliptical shape, or a polygonal shape.

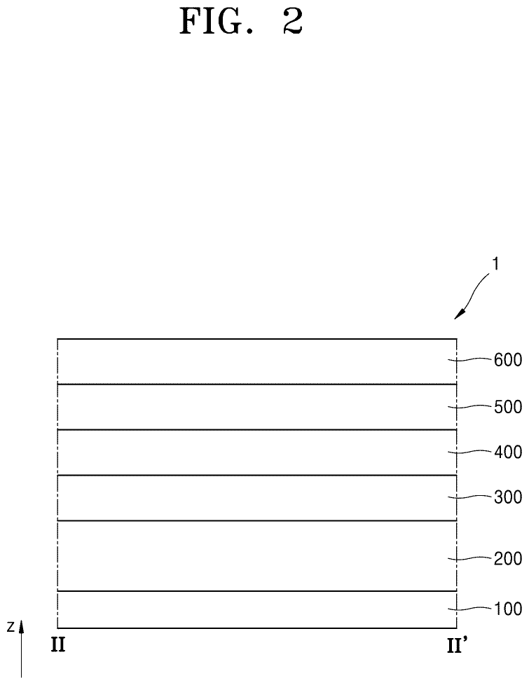

FIG. 2 is a cross-sectional view schematically illustrating a display apparatus taken along line II-II′ of FIG. 1 according to an embodiment.

An embodiment of FIG. 2 may correspond to a cross-section of a mother substrate of a display apparatus or a cross-section of a unit display apparatus. The following will be described assuming that the embodiment of FIG. 2 corresponds to the display apparatus 1 for convenience of explanation.

Referring to FIG. 2, the display apparatus 1 according to an embodiment may include a substrate 100, a display layer 200, an encapsulation layer 300, a touch layer 400, an optical functional layer 500, and a physical functional layer 600.

The substrate 100 may include glass or a polymer resin. Examples of the polymer resin may include polyethersulfone, polyacrylate, polyether imide, polyethylene naphthalate, polyethylene terephthalate, polyphenylene sulfide, polyarylate, polyimide, polycarbonate, and cellulose acetate propionate. The substrate 100 including the polymer resin may be flexible, rollable, or bendable. The substrate 100 may have a multi-layer structure including a layer including a polymer resin and an inorganic layer (not shown).

The display layer 200 may include a light-emitting diode as a display element, a thin-film transistor electrically connected to the light-emitting diode, and insulating layers located between the light-emitting diode and the thin-film transistor.

The encapsulation layer 300 may be located on the display layer 200. Alternatively, the display layer 200 may be covered and sealed by the encapsulation layer 300. The encapsulation layer 300 may include at least one inorganic encapsulation layer and at least one organic encapsulation layer.

In some embodiments, the display apparatus 1 may include an encapsulation substrate (not shown) formed of a glass material, instead of the encapsulation layer 300. The encapsulation substrate may be located on the display layer 200, and the display layer 200 may be located between the substrate 100 and the encapsulation substrate. There may be a gap between the encapsulation substrate and the display layer 200, and the gap may be filled with a filler.

The touch layer 400 may be located on the encapsulation layer 300. The touch layer 400 may be configured to sense an external input, for example, a touch of an object such as a finger or a stylus pen, so that the display apparatus 1 obtains coordinate information corresponding to a touch position. The touch layer 400 may include a touch electrode and trace lines connected to the touch electrode. The touch layer 400 may sense an external input by using a mutual capacitance method or a self-capacitance method.

In an embodiment, the touch layer 400 may be formed directly on the encapsulation layer 300. Alternatively, the touch layer 400 may be separately formed and then may be adhered to the encapsulation layer 300 through an adhesive layer such as an optically clear adhesive (OCA).

The optical functional layer 500 may be located on the touch layer 400. The optical functional layer 500 may include a light blocking layer and/or a color filter described below. The color filter may have a color corresponding to light emitted from a light-emitting element located under each color filter.

The physical functional layer 600 may be located on the optical functional layer 500. A part of the physical functional layer 600 may function as an overcoat layer for planarizing steps formed by the optical functional layer 500. Also, the physical functional layer 600 may include a layer for absorbing impact to protect layers located under the physical functional layer 600 from external impact.

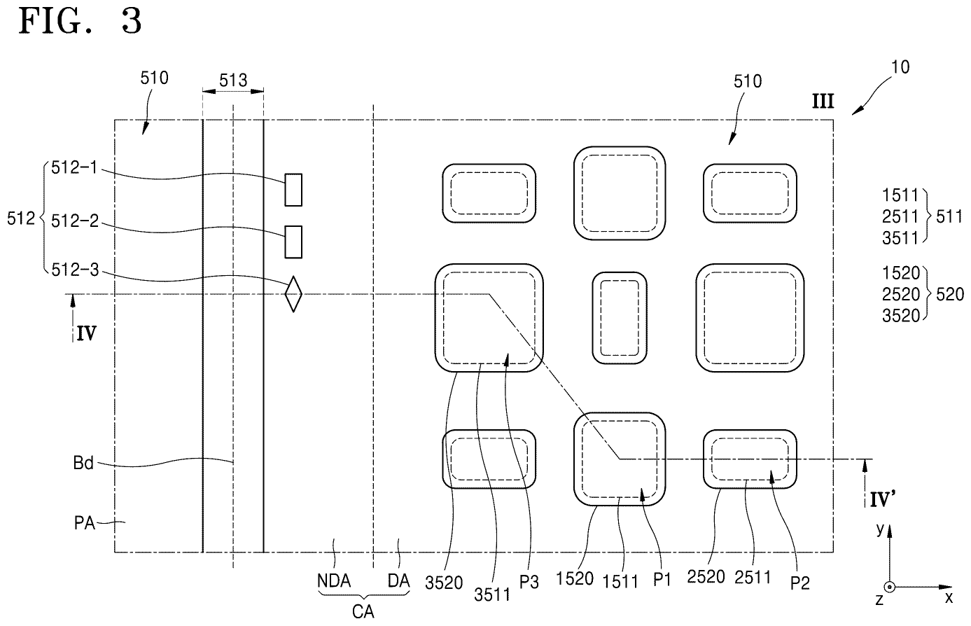

FIG. 3 is an enlarged plan view illustrating a part of a mother substrate of a display apparatus, particularly illustrating a portion III of FIG. 1, according to an embodiment.

Referring to FIG. 3, a plurality of sub-pixels each emitting light of a specific color may be located in the first area CA.

The sub-pixels may include first to third sub-pixels P1, P2, and P3 emitting light of different colors. For example, the first sub-pixel P1 may emit red light, the second sub-pixel P2 may emit green light, and the third sub-pixel P3 may emit blue light. Each sub-pixel may include a light-emitting device emitting light of a corresponding color.

Referring to FIG. 2 together with FIG. 3, components of the optical functional layer 500 are illustrated in FIG. 3. For example, a light blocking layer 510 and color filters 520 of the optical functional layer 500 are illustrated in FIG. 3. The optical functional layer 500 may include a light transmitting portion that transmits light and a light blocking portion that blocks light. The light transmitting portion of the optical functional layer 500 may be a portion that transmits light emitted from a light-emitting device of each sub-pixel. Accordingly, the light transmitting portion may overlap each sub-pixel (e.g., each of the first sub-pixel P1, the second sub-pixel P2, and the third sub-pixel P3). For example, in the present embodiment, the light transmitting portion of the optical functional layer 500 may include first openings 511 of the light blocking layer 510 and the color filters 520 located in the first openings 511 of the light blocking layer 510. The light blocking portion of the optical functional layer 500 may be a portion that blocks light emitted from a light-emitting device of each sub-pixel. For example, in the present embodiment, the light blocking portion of the optical functional layer 500 may include the light blocking layer 510.

The light blocking layer 510 may be located in both the first area CA and the second area PA. For example, the light blocking layer 510 may include a portion overlapping the first area CA and a portion overlapping the second area PA.

The light blocking layer 510 may include a first opening 511 located in the display area DA of the first area CA. A plurality of first openings 511 may be provided. For example, the light blocking layer 510 may include 1-1 to 1-3 openings 1511, 2511, and 3511 located in the display area DA.

The first openings 511 may respectively be disposed in an area corresponding sub-pixels. For example, the 1-1 opening 1511 may be located in the light blocking layer 510 in an area corresponding to the first sub-pixel P1. The 1-2 opening 2511 may be located in the light blocking layer 510 in an area corresponding to the second sub-pixel P2. The 1-3 opening 3511 may be located in the light blocking layer 510 in an area corresponding to the third sub-pixel P3.

The color filter 520 may be located on the light blocking layer 510. A plurality of color filters 520 may be provided, and may be located on the light blocking layer 510 respectively in an area corresponding to the sub-pixels (or the first openings 511). For example, a first color filter 1520 may be located on the light blocking layer 510 in an area corresponding to the first sub-pixel P1 or the 1-1 opening 1511. A second color filter 2520 may be located on the light blocking layer 510 in an area corresponding to the second sub-pixel P2 or the 1-2 opening 2511. A third color filter 3520 may be located on the light blocking layer 510 in an area corresponding to the third sub-pixel P3 or the 1-3 opening 3511.

Each color filter 520 may transmit light of the same color as light emitted from a corresponding sub-pixel. In an embodiment, the first sub-pixel P1 may emit red light and the first color filter 1520 may transmit red light. The second sub-pixel P2 may emit green light and the second color filter 2520 may transmit green light. The third sub-pixel P3 may emit blue light and the third color filter 3520 may transmit blue light.

A size of each color filter 520 may be greater than a size of the corresponding first opening 511. In an embodiment, a size of the first color filter 1520 may be greater than a size of the 1-1 opening 1511. A size of the second color filter 2520 may be greater than a size of the 1-2 opening 2511. A size of the third color filter 3520 may be greater than a size of the 1-3 opening 3511. Accordingly, the corresponding first opening 511 may be completely filled by each color filter 520.

Although the first openings 511 and the color filters 520 have substantially quadrangular shapes with rounded corners in FIG. 3, the disclosure is not limited thereto. Each of the first openings 511 and/or each of the color filters 520 may have any of various shapes such as a circular shape, an elliptical shape, or a polygonal shape.

The light blocking layer 510 may include an alignment mark, for example, a second opening 512, located in the non-display area NDA of the first area CA.

The second opening 512 may include a plurality of openings. For example, the second opening 512 may include a 2-1 opening 512-1, a 2-2 opening 512-2, and a 2-3 opening 512-3.

The 2-1 to 2-3 openings 512-1, 512-2, and 512-3 may be arranged along one direction. For example, the 2-1 to 2-3 openings 512-1, 512-2, and 512-3 may be arranged along a ±y direction. In an embodiment, the 2-2 opening 512-2 may be located in the +y direction of the 2-3 opening 512-3, and the 2-1 opening 512-1 may be located in the +y direction of the 2-2 opening 512-2.

The second opening 512 may be located adjacent to a boundary Bd between the first area CA and the second area PA. In an embodiment, the boundary Bd between the first area CA and the second area PA may extend along the ±y direction, the second opening 512 may be disposed adjacent to the boundary Bd between the first area CA and the second area PA and may include the 2-1 to 2-3 openings 512-1, 512-2, and 512-3 arranged along the ±y direction.

When the mother substrate 10 of the display apparatus is cut using a laser in a scribing process, the cutting may be performed along the boundary Bd between the first area CA and the second area PA. In this case, the second opening 512 may be located adjacent to the boundary Bd between the first area CA and the second area PA in the first area CA in the non-display area NDA, thereby functioning as an alignment mark.

Planar shapes of some of the 2-1 to 2-3 openings 512-1, 512-2, and 512-3 may be different from planar shapes of others. In an embodiment, as shown in FIG. 3, each of the 2-1 and 2-2 openings 512-1 and 512-2 may have a substantially quadrangular shape in which a length in the ±y direction is greater than a length in a ±x direction, and the 2-3 opening 512-3 may have a substantially diamond shape in which a length in the ±y direction is greater than a length in the ±x direction.

Because shapes of some of the 2-1 to 2-3 openings 512-1, 512-2, and 512-3 are different from the rest, the direction of cutting the mother substrate may be determined. In an embodiment, the mother substrate 10 may be cut in the −y direction by setting a laser to pass in the order of rectangle-rectangle-diamond. In another embodiment, the mother substrate 10 may be cut in the +y direction by setting a laser to pass in the order of diamond-rectangle-rectangle. However, the disclosure is not limited thereto, and the number, arrangement, and shape of openings included in the second opening 512 may be changed in various ways.

The light blocking layer 510 may include a groove 513 located between the first area CA and the second area PA. The groove 513 may be an area in which the light blocking layer 510 is removed.

The groove 513 may be disposed in the border Bd between the first area CA and the second area PA. Also, the groove 513 may be disposed in a portion of the first area CA and a portion of the second area PA.

In other words, the groove 513 may extend along the border Bd between the first area CA and the second area PA. For example, in FIG. 3, the groove 513 may extend in the ±y direction along the border Bd between the first area CA and the second area PA. When viewed based on the entire unit display apparatus as shown in FIG. 1, the groove 513 may have a shape extending along the border Bd between the first area CA and the second area PA and surrounding the first area CA.

The groove 513 may be disposed in the border Bd between the first area CA and the second area PA, and the second opening 512 may be located adjacent to the border Bd between the first area CA and the second area PA in the first area CA in the non-display area NDA. In this case, the second opening 512 and the groove 513 may be spaced apart from each other. For example, a side surface of the groove 513 located in the first area CA (or the non-display area NDA) among both side surfaces of the groove 513 and a side surface of the second opening 512 may be spaced apart from each other. Alternatively, a part of the light blocking layer 510 may be located between the second opening 512 and the groove 513.

Although the groove 513 is horizontally symmetrical about the boundary Bd between the first area CA and the second area PA in FIG. 3, the disclosure is not limited thereto.

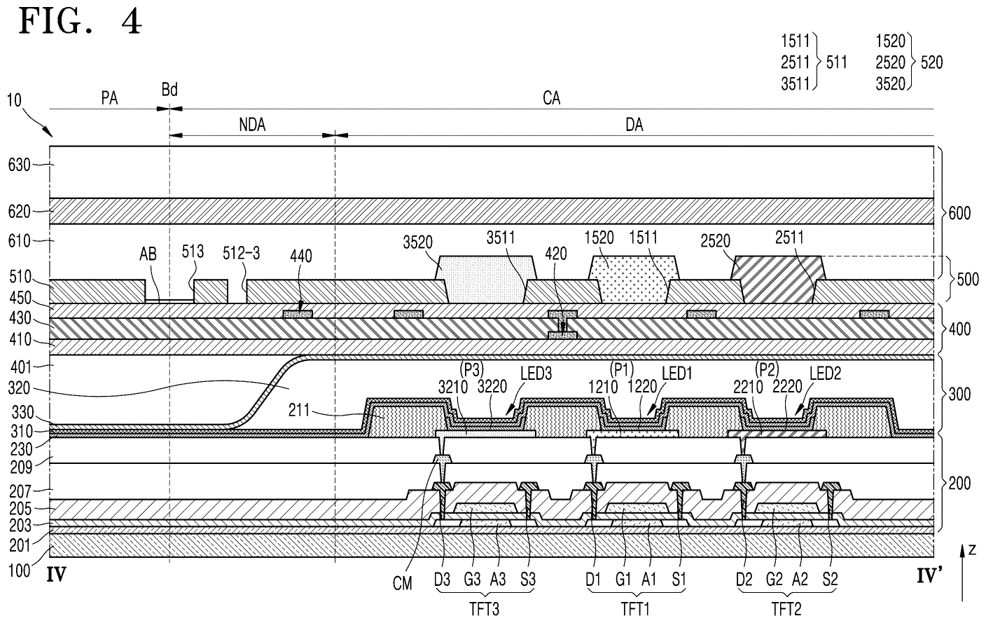

FIG. 4 is a cross-sectional view illustrating a part of a mother substrate of a display apparatus, taken along line IV-IV′ of FIG. 3 according to an embodiment.

Referring to FIG. 4, the display layer 200 including a plurality of sub-pixels may be located on the substrate 100 in the display area DA. In an embodiment, the first to third sub-pixels P1, P2, and P3 may be located on the substrate 100. The first to third sub-pixels P1, P2, and P3 may include first to third light-emitting diodes LED1, LED2, and LED3 emitting light of certain colors.

The first to third light-emitting diodes LED1, LED2, and LED3 may include first to third sub-pixel electrodes 1210, 2210, and 3210 and first to third intermediate layers 1220, 2220, and 3220, respectively.

The substrate 100 may include a glass or plastic polymer resin. The substrate 100 including a polymer resin may be flexible, rollable, or bendable. The substrate 100 may have a multi-layer structure including a layer including a polymer resin and an inorganic layer (not shown).

The first to third intermediate layers 1220, 2220, and 3220 respectively corresponding to the first to third sub-pixels P1, P2, and P3 may be respectively electrically connected to first to third thin-film transistors TFT1, TFT2, and TFT3 on the substrate 100.

The first intermediate layer 1220 corresponding to the first sub-pixel P1 may be electrically connected to the first thin-film transistor TFT1 through the first sub-pixel electrode 1210. The first thin-film transistor TFT1 may include a first active layer A1, a first gate electrode G1 overlapping a part of the first active layer A1, and a first source electrode S1 and a first drain electrode D1 each directly contacting a part of the first active layer A1.

The second intermediate layer 2220 corresponding to the second sub-pixel P2 may be electrically connected to the second thin-film transistor TFT2 through the second sub-pixel electrode 2210. The second thin-film transistor TFT2 may include a second active layer A2, a second gate electrode G2 overlapping a part of the second active layer A2, and a second source electrode S2 and a second drain electrode D2 each directly contacting a part of the second active layer A2.

The third intermediate layer 3220 corresponding to the third sub-pixel P3 may be electrically connected to the third thin-film transistor TFT3 through the third sub-pixel electrode 3210. The third thin-film transistor TFT3 may include a third active layer A3, a third gate electrode G3 overlapping a part of the third active layer A3, and a third source electrode S3 and a third drain electrode D3 each directly contacting the part of the third active layer A3.

Each of the first to third gate electrodes G1, G2, and G3 may include at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single or multi-layer structure including the above material.

A buffer layer 201 for preventing penetration of impurities may be located between the substrate 100 and the first to third active layers A1, A2, and A3. A gate insulating layer 203 may be located between the first to third active layers A1, A2, and A3 and the first to third gate electrodes G1, G2, and G3. An interlayer insulating layer 205 may be located on the first to third gate electrodes G1, G2, and G3. Each of the buffer layer 201, the gate insulating layer 203, and the interlayer insulating layer 205 may include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The first to third source electrodes S1, S2, and S3 may be located on the interlayer insulating layer 205, and may be respectively connected to the first to third active layers A1, A2, and A3 through contact holes formed in the interlayer insulating layer 205 and the gate insulating layer 203. Each of the first to third source electrodes S1, S2, and S3 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may have a single or multi-layer structure.

The first to third drain electrodes D1, D2, and D3 may be located on the interlayer insulating layer 205, and may be respectively connected to the first to third active layers A1, A2, and A3 through contact holes formed in the interlayer insulating layer 205 and the gate insulating layer 203. Each of the first to third drain electrodes D1, D2, and D3 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may have a single or multi-layer structure. In some embodiments, the first to third source electrodes S1, S2, and S3 and the first to third drain electrodes D1, D2, and D3 may include the same material.

A first organic insulating layer 207 may be located on the first to third thin-film transistors TFT1, TFT2, and TFT3. For example, the first organic insulating layer 207 may be located to cover the first to third source electrodes S1, S2, and S3 and the first to third drain electrodes D1, D2, and D3. The first organic insulating layer 207 may include an organic insulating material such as acryl, benzocyclobutene, polyimide, or hexamethyldisiloxane. The first organic insulating layer 207 may include a plurality of contact holes. For example, the first organic insulating layer 207 may include a plurality of contact holes respectively exposing the first to third drain electrodes D1, D2, and D3.

A connection metal CM may be located on the first organic insulating layer 207. The connection metal CM may include aluminum (Al), copper (Cu), and/or titanium (Ti), and may have a single or multi-layer structure including the above material. A plurality of connection metals CM may be provided, and may respectively overlap the first to third drain electrodes D1, D2, and D3. A part of each of the connection metals CM may be located in the contact hole formed in the first organic insulating layer 207. For example, the connection metals CM may respectively directly contact the first to third drain electrodes D1, D2, and D3 through the contact holes formed in the first organic insulating layer 207.

A second organic insulating layer 209 may be located between the first organic insulating layer 207 and the first to third sub-pixel electrodes 1210, 2210, and 3210. The second organic insulating layer 209 may include an organic insulating material such as acryl, benzocyclobutene, polyimide, or hexamethyldisiloxane. The second organic insulating layer 209 may include contact holes respectively exposing the connection metals CM.

The first to third sub-pixel electrodes 1210, 2210, and 3210 may be located on the second organic insulating layer 209. Each of the first to third sub-pixel electrodes 1210, 2210, and 3210 may be formed of a reflective electrode. Each of the first to third sub-pixel electrodes 1210, 2210, and 3210 may be formed by forming a reflective film formed of silver (Ag), magnesium (Mg), aluminum (Al), platinum (Pt), palladium (Pd), gold (Au), nickel (Ni), neodymium (Nd), iridium (Ir), chromium (Cr) or a compound thereof and locating a film formed of ITO, IZO, ZnO, or In₂O₃ on the reflective film. In an embodiment, each of the first to third sub-pixel electrodes 1210, 2210, and 3210 may have a structure in which an ITO layer, an Ag layer, and an ITO layer are sequentially stacked. However, the disclosure is not limited thereto and various modifications may be made. For example, the first to third sub-pixel electrodes 1210, 2210, and 3210 may be formed of any of various materials, and may have any of various structures such as a single or multi-layer structure.

The first to third sub-pixel electrodes 1210, 2210, and 3210 may be electrically connected to the connection metals CM through the contact holes formed in the second organic insulating layer 209.

Although the first to third thin-film transistors TFT1, TFT2, and TFT3 and the first to third sub-pixel electrodes 1210, 2210, and 3210 are electrically connected to each other through the connection metals CM according to an embodiment of FIG. 4, the disclosure is not limited thereto. In another embodiment, the connection metal CM may be omitted, and one organic insulating layer may be located between the first to third thin-film transistors TFT1, TFT2, and TFT3 and the first to third sub-pixel electrodes 1210, 2210, and 3210. Alternatively, three or more organic insulating layers may be located between the first to third thin-film transistors TFT1, TFT2, and TFT3 and the first to third sub-pixel electrodes 1210, 2210, and 3210, and the first to third thin-film transistors TFT1, TFT2, and TFT3 and the first to third sub-pixel electrodes 1210, 2210, and 3210 may be electrically connected to each other through a plurality of connection metals.

A sub-pixel defining layer 211 may cover edge portions (or edges) of the first to third sub-pixel electrodes 1210, 2210, and 3210. In other words, the sub-pixel defining layer 211 may include a plurality of openings through which central portions of the first to third sub-pixel electrodes 1210, 2210, and 3210 are exposed. Each opening of the sub-pixel defining layer 211 may define an emission area of each of the first to third sub-pixels P1, P2, and P3.

The first to third intermediate layers 1220, 2220, and 3220 may be located on the first to third sub-pixel electrodes 1210, 2210, and 3210, respectively. For example, the first intermediate layer 1220 may be located on the first sub-pixel electrode 1210 in the opening of the sub-pixel defining layer 211. The second intermediate layer 2220 may be located on the second sub-pixel electrode 2210 in an opening of the sub-pixel defining layer 211. The third intermediate layer 3220 may be located on the third sub-pixel electrode 3210 in the opening of the sub-pixel defining layer 211.

Each of the first to third intermediate layers 1220, 2220, and 3220 may include an organic emission layer including a low molecular weight material or a high molecular weight material. Each of the first to third intermediate layers 1220, 2220, and 3220 may have a single or multi-layer structure including a hole injection layer, a hole transport layer, an organic emission layer, an electron transport layer, and/or an electron injection layer.

A counter electrode 230 may be located on the first to third intermediate layers 1220, 2220, and 3220. The counter electrode 230 may be integrally formed to cover the first to third intermediate layers 1220, 2220, and 3220. The counter electrode 230 may be formed as a (semi-) transparent electrode. When the counter electrode 230 is a (semi-) transparent electrode, the counter electrode 230 may include at least one material selected from among Ag, Al, Mg, Li, Ca, Cu, LiF/Ca, LiF/Al, MgAg, and CaAg, and may be formed as a thin film having a thickness of several to tens of nanometers (nm). A configuration and a material of the counter electrode 230 are not limited thereto, and various modifications may be made.

The encapsulation layer 300 may be located on the counter electrode 230. The encapsulation layer 300 may include at least one inorganic encapsulation layer and at least one organic encapsulation layer. For example, as shown in FIG. 4, the encapsulation layer 300 may include a first inorganic encapsulation layer 310, an organic encapsulation layer 320, and a second inorganic encapsulation layer 330 which are sequentially stacked.

Each of the first inorganic encapsulation layer 310 and the second inorganic encapsulation layer 330 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). Each of the first inorganic encapsulation layer 310 and the second inorganic encapsulation layer 330 may have a single or multi-layer structure including the above inorganic insulating material.

The organic encapsulation layer 320 may relieve internal stress of the first inorganic encapsulation layer 310 and/or the second inorganic encapsulation layer 330. The organic encapsulation layer 320 may include a polymer-based material. For example, the organic encapsulation layer 320 may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate or polyacrylic acid), or any combination thereof.

The encapsulation layer 300 may have a multi-layer structure including the first inorganic encapsulation layer 310, the organic encapsulation layer 320, and the second inorganic encapsulation layer 330. In this case, even when a crack occurs in the encapsulation layer 300, the crack may not propagate between the first inorganic encapsulation layer 310 and the organic encapsulation layer 320 or between the organic encapsulation layer 320 and the second inorganic encapsulation layer 330. The encapsulation layer 300 may prevent or minimize penetration of external moisture or oxygen into the display layer 200.

Although not shown in FIG. 4, in another embodiment, a capping layer may be further located between the encapsulation layer 300 and the counter electrode 230. For example, in another embodiment, a capping layer (not shown) may be located between the first inorganic encapsulation layer 310 and the counter electrode 230. The capping layer may improve the luminous efficiency of the first to third light-emitting diodes LED1, LED2, and LED3 by causing constructive interference.

The second inorganic encapsulation layer 330 may directly contact the first inorganic encapsulation layer 310 in the non-display area NDA. For example, the second inorganic encapsulation layer 330 may surround a side surface of the organic encapsulation layer 320 in the non-display area NDA, and may contact the first inorganic encapsulation layer 310 in the non-display area NDA.

In the non-display area NDA and the second area PA, a planarization layer 401 may be located between the touch layer 400 and the encapsulation layer 300. For example, the planarization layer 401 may be located in a part of the non-display area NDA and the second area PA, and may be located between the second inorganic encapsulation layer 330 and a first touch insulating layer 410. A part of the planarization layer 401 may cover a part of the second inorganic encapsulation layer 330. The planarization layer 401 may provide a flat surface on which the touch layer 400 may be located.

Although not shown in FIG. 4, in another embodiment, a dam may be located in the non-display area NDA to prevent the organic encapsulation layer 320 from moving in one direction.

The touch layer 400 may be located on the encapsulation layer 300. The touch layer 400 may include the first touch insulating layer 410, a first conductive layer 420, a second touch insulating layer 430, a second conductive layer 440, and a third touch insulating layer 450.

The first touch insulating layer 410 may be located on the second inorganic encapsulation layer 330 of the encapsulation layer 300 to planarize a surface on which the first conductive layer 420, etc. are located. The first touch insulating layer 410 may include an inorganic insulating material such as silicon oxide (SiOₓ), silicon nitride (SiNₓ), or silicon oxynitride (SiON). In some embodiments, the first touch insulating layer 410 may include an organic insulating material. In another embodiment, the first touch insulating layer 410 may be omitted, and the first conductive layer 420 may be located on the second inorganic encapsulation layer 330 of the encapsulation layer 300 or the planarization layer 401.

The second touch insulating layer 430 may be located on the first conductive layer 420. The second touch insulating layer 430 may include an inorganic material or an organic material. When the second touch insulating layer 430 includes an inorganic material, the second touch insulating layer 430 may include at least one material selected from the group consisting of silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), and silicon oxynitride (SiON). When the second touch insulating layer 430 includes an organic material, the second touch insulating layer 430 may include at least one material selected from the group consisting of an acrylic resin, a methacrylic resin, polyisoprene, a vinyl-based resin, an epoxy-based resin, a urethane-based resin, a cellulose-based resin, and a perylene-based resin.

The second conductive layer 440 may be located on the second touch insulating layer 430. The second conductive layer 440 may function as a sensor that detects a user's touch input. The first conductive layer 420 may function as a connector that connects the patterned second conductive layer 440 in one direction. In an embodiment, both the first conductive layer 420 and the second conductive layer 440 may function as sensors. In this case, the first conductive layer 420 and the second conductive layer 440 may be electrically connected to each other through a contact hole. When both the first conductive layer 420 and the second conductive layer 440 function as sensors, the resistance of the touch electrode may be reduced and thus the user's touch input may be quickly detected.

In an embodiment, each of the first conductive layer 420 and the second conductive layer 440 may have a structure through which light emitted from a light-emitting diode may pass, for example, a mesh structure. In this case, the first conductive layer 420 and the second conductive layer 440 may not overlap an emission area of the light-emitting diode.

Each of the first conductive layer 420 and the second conductive layer 440 may include a metal layer or a transparent conductive layer. The metal layer may include molybdenum (Mo), silver (Ag), titanium (Ti), copper (Cu), aluminum (Al), and an alloy thereof. The transparent conductive layer may include a transparent conductive oxide such as indium tin oxide (ITO), indium zinc oxide (IZO), zinc oxide (ZnO), or indium tin zinc oxide (ITZO), a conductive polymer such as PEDOT, metal nanotubes, carbon nanotubes, or graphene.

The third touch insulating layer 450 may be located on the second conductive layer 440. The third touch insulating layer 450 may include an inorganic material or an organic material. When the third touch insulating layer 450 includes an inorganic material, the third touch insulating layer 450 may include at least one material selected from the group consisting of silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), and silicon oxynitride (SiON). When the third touch insulating layer 450 includes an organic material, the third touch insulating layer 450 may include at least one material selected from the group consisting of an acrylic resin, a methacrylic resin, polyisoprene, a vinyl-based resin, an epoxy-based resin, a urethane-based resin, a cellulose-based resin, and a perylene-based resin.

The optical function layer 500 may be located on the touch layer 400. The optical functional layer 500 may include the light blocking layer 510 and the color filter 520. The light blocking layer 510 may include a material that absorbs external light, and thus, the visibility of the display apparatus may be improved.

The light blocking layer 510 may include the first openings 511 which are disposed in areas corresponding to the first to third sub-pixels P1, P2, and P3. A plurality of first openings 511 may be provided. For example, the first opening 511 may include the 1-1 opening 1511 disposed in an area corresponding to the first sub-pixel P1, the 1-2 opening 2511 disposed in an area corresponding to the second sub-pixel P2, and the 1-3 opening 3511 disposed in an area corresponding to the third sub-pixel P3. The 1-1 to 1-3 openings 1511, 2511, and 3511 may respectively be disposed in the first to third sub-pixels P1, P2, and P3 and be disposed in an area corresponding to the openings formed in the sub-pixel defining layer 211, and may have sizes equal to or greater than sizes of the openings formed in the sub-pixel defining layer 211. In other words, sizes of the 1-1 to 1-3 openings 1511, 2511, and 3511 may be equal to or greater than sizes of emission areas of the first to third sub-pixels P1, P2, and P3.

The color filter 520 may be located on the light blocking layer 510 in an area corresponding to the first opening 511. For example, the color filter 520 may include the first to third color filters 1520, 2520, and 3520, and the first to third color filters 1520, 2520, and 3520 may be located on the light blocking layer 510 to in areas respectively corresponding to the 1-1 to 1-3 openings 1511, 2511, and 3511.

Apart of the color filter 520 may be located in the first opening 511. For example, a portion of the first color filter 1520 may be located in the 1-1 opening 1511, and another portion may protrude beyond a top surface of the 1-1 opening 1511 and may be located on the light blocking layer 510. A portion of the second color filter 2520 may be located in the 1-2 opening 2511, and another portion may protrude beyond a top surface of the 1-2 opening 2511 and may be located on the light blocking layer 510. A portion of the third color filter 3520 may be located in the 1-3 opening 3511, and another portion may protrude beyond a top surface of the 1-3 opening 3511 and may be located on the light blocking layer 510.

A width of the color filter 520 may be greater than a width of the first opening 511. For example, a width of the first color filter 1520 may be greater than a width of the 1-1 opening 1511. A width of the second color filter 2520 may be greater than a width of the 1-2 opening 2511. A width of the third color filter 3520 may be greater than a width of the 1-3 opening 3511. Accordingly, as shown in FIG. 3, a size of each color filter 520 may be greater than a size of each first opening 511.

The color filter 520 may transmit light of the same color as a corresponding sub-pixel. For example, the first sub-pixel P1 may emit red light, and the first color filter 1520 may transmit red light. The second sub-pixel P2 may emit green light, and the second color filter 2520 may transmit green light. The third sub-pixel P3 may emit blue light, and the third color filter 3520 may transmit blue light. Accordingly, the visibility of the display apparatus may be further improved.

Although the 2-3 opening 512-3 is mainly described hereinunder, characteristics of the 2-3 opening 512-3 may apply to the second opening 512 (see FIG. 3) including the 2-1 and 2-2 openings 512-1 and 512-2 (see FIG. 3).

The 2-3 opening 512-3 of the light blocking layer 510 may be located adjacent to the boundary Bd between the first area CA and the second area PA. In an embodiment, the 2-3 opening 512-3 may be located in the first area CA (or the non-display area NDA) to be adjacent to the boundary Bd between the first area CA and the second area PA. In another embodiment, the 2-3 opening 512-3 may be located in the second area PA to be adjacent to the boundary Bd between the first area CA and the second area PA.

The 2-3 opening 512-3 may formed through the light blocking layer 510. In other words, the 2-3 opening 512-3 may be a through hole formed through the light blocking layer 510. Accordingly, a portion of a top surface of the third touch insulating layer 450 may be exposed through the 2-3 opening 512-3.

The light blocking layer 510 may include the groove 513 disposed in an area corresponding to the boundary Bd between the first area CA and the second area PA. The groove 513 and the 2-3 opening 512-3 may be located adjacent to each other and may be spaced apart from each other. For example, a portion of the light blocking layer 510 may be located between the 2-3 opening 512-3 and the groove 513.

The groove 513 may be formed through the light blocking layer 510. Accordingly, a portion of a top surface of the third touch insulating layer 450 may be exposed through the groove 513.

The physical functional layer 600 may be located on the optical functional layer 500. The physical functional layer 600 may include a first adhesive layer 610, a second adhesive layer 630, and an impact absorbing layer 620 located between the first and second adhesive layers 610 and 630.

The first adhesive layer 610 may be located on the light blocking layer 510 and may cover the light blocking layer 510 and the color filter 520. The first adhesive layer 610 may have an adhesive force that may be changed by pressure applied thereto and may have a high transmittance. In an embodiment, the first adhesive layer 610 may include a pressure sensitive adhesive.

The first adhesive layer 610 may function as an overcoat layer that covers and planarizes steps formed by the light blocking layer 510 and the color filter 520.

The first adhesive layer 610 may have fluidity. Accordingly, a portion of the first adhesive layer 610 may be located in the 2-3 opening 512-3 and/or the groove 513 of the light blocking layer.

A bubble layer AB may be formed between a portion of the first adhesive layer 610 located in the groove 513 and the top surface of the third touch insulating layer 450 exposed through the groove 513. In other words, the bubble layer AB may be located in the groove 513 of the light blocking layer 510 and may be located between the first adhesive layer 610 and the third touch insulating layer 450.

Although not shown in FIG. 4, in another embodiment, another bubble layer may be located between the first adhesive layer 610 and the third touch insulating layer 450 in the 2-3 opening 512-3. Alternatively, in another embodiment, the first adhesive layer 610 and the third touch insulating layer 450 may not be in direct contact with each other in the 2-3 opening 512-3.

The impact absorbing layer 620 may be located on the first adhesive layer 610. The impact absorbing layer 620 may absorb impact that may be applied to layers located under the impact absorbing layer 620, for example, the display layer 200 or the touch layer 400. The impact absorbing layer 620 may include a resin having high flexibility, for example, polyethylene terephthalate (PET). Because the impact absorbing layer 620 is included, the bendable and foldable characteristics of the display apparatus may be improved.

The second adhesive layer 630 may be located on the impact absorbing layer 620. The second adhesive layer 630 may include the same material as the first adhesive layer 610.

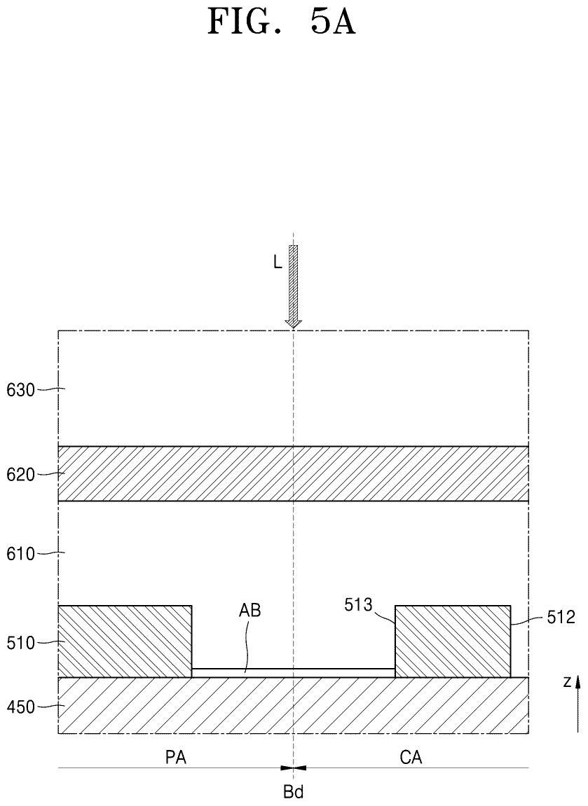

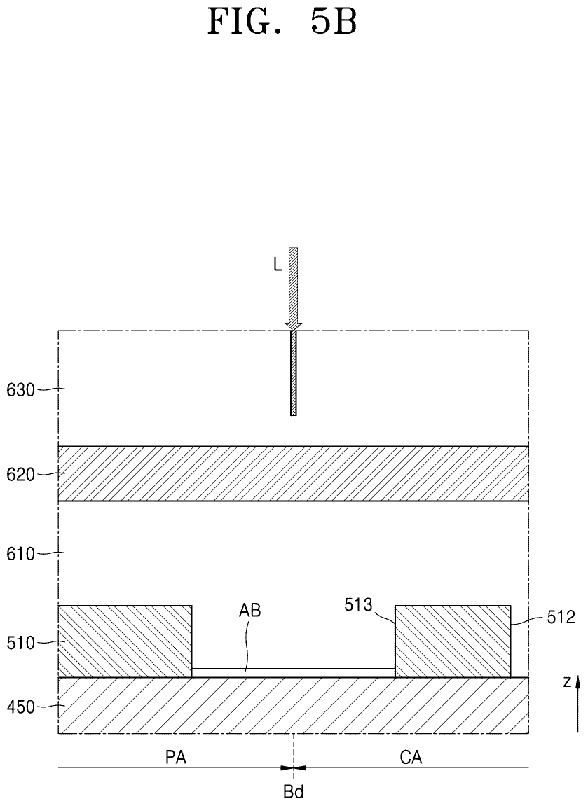

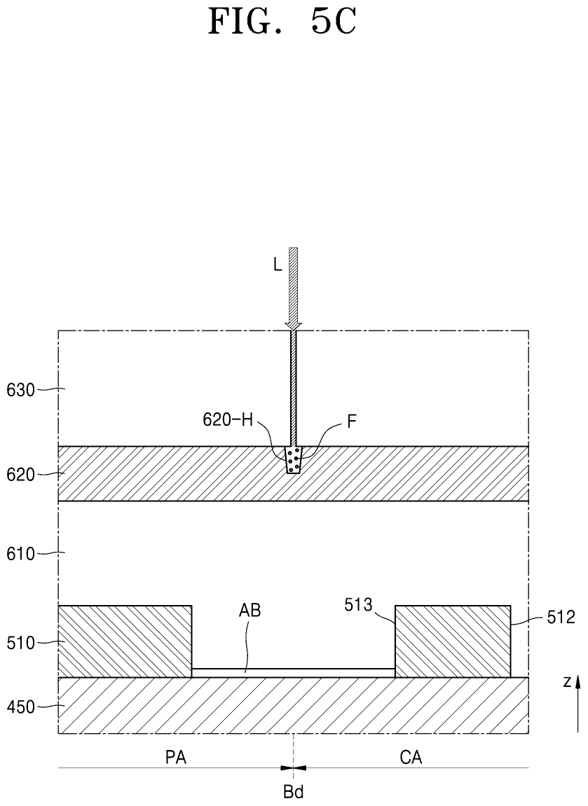

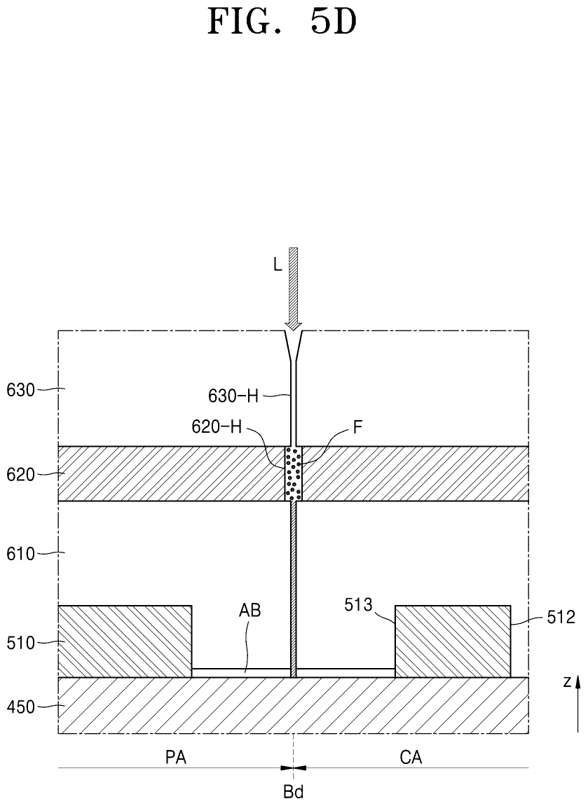

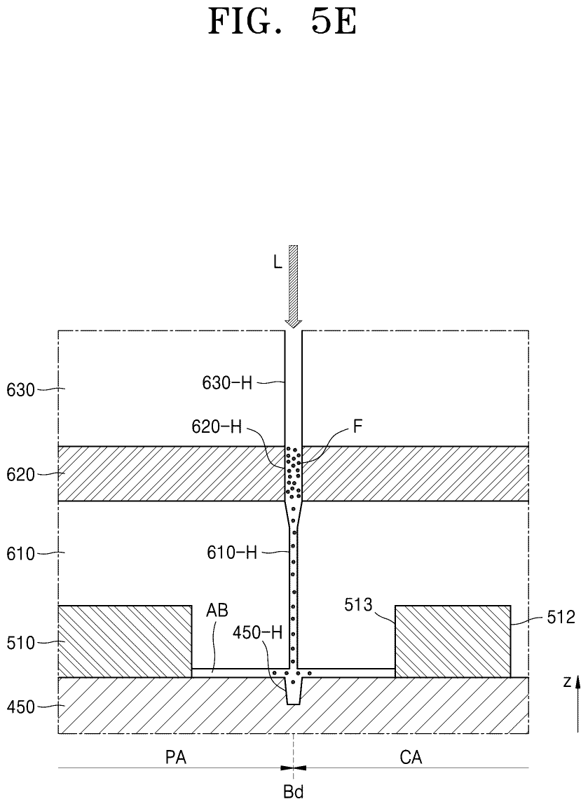

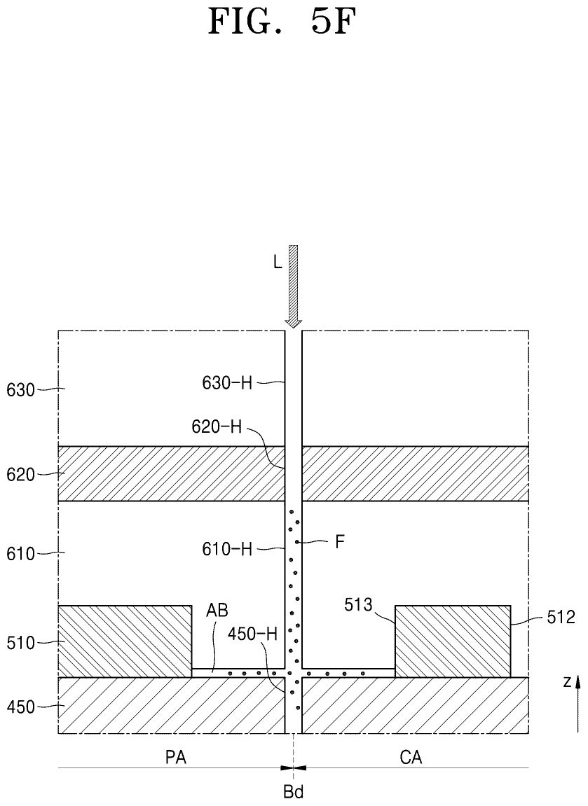

FIGS. 5A to 5F are cross-sectional views illustrating states in process steps of a method of manufacturing a display apparatus according to an embodiment.

For example, FIGS. 5A to 5F may be enlarged cross-sectional views illustrating a process of cutting a mother substrate of a display apparatus by using a laser.

Referring to FIG. 5A, a laser L may be incident on a top surface of the second adhesive layer 630.

The laser L may be incident in a direction perpendicular to the top surface of the second adhesive layer 630, for example, in a −z direction. An incident path of the laser L may match the boundary Bd between the first area CA and the second area PA.

Referring to FIG. 5B, the laser L may be transmitted through the second adhesive layer 630. Each of the first and second adhesive layers 610 and 630 may include a material having a high transmittance. Accordingly, the second adhesive layer 630 may not be cut when the laser L is incident on the second adhesive layer 630. The laser L incident on the second adhesive layer 630 may be transmitted through the second adhesive layer 630 and may travel toward the impact absorbing layer 620 located under the second adhesive layer 630.

Referring to FIG. 5C, the laser L may completely pass through the second adhesive layer 630 and then may be incident on the impact absorbing layer 620.

The impact absorbing layer 620 is a layer having a lower transmittance than the second adhesive layer 630 and may be cut at the same time as the laser L is incident. That is, the laser L is incident on the second adhesive layer 630 first, however cutting may be performed on the impact absorbing layer 620 first.

A hole 620-H may be formed in the impact absorbing layer 620 at a position where the laser L is incident. As a part of the impact absorbing layer 620 is removed by the laser L, fumes F may be generated. In a current step of the process, the hole 620-H of the impact absorbing layer 620 may be a blind hole. Accordingly, there is no space where particles of the fumes F may move, and thus, the particles of the fumes may be located in the hole 620-H of the impact absorbing layer 620.

Referring to FIG. 5D, the laser L passing through the impact absorbing layer 620, and may pass through the first adhesive layer 610.

As the laser L passes through the impact absorbing layer 620, the hole 620-H of the impact absorbing layer 620 may change to a through hole. The amount of fumes F generated may increase compared to when the hole 620-H of the impact absorbing layer 620 is a blind hole (e.g., before the laser L penetrates the impact absorbing layer 620).

Because a sufficient time has passed since the laser L was irradiated through the second adhesive layer 630, the second adhesive layer 630 may also be cut by the laser L. Accordingly, a hole 630-H may begin to be formed in the second adhesive layer 630. The hole 630-H of the second adhesive layer 630 may be a through hole.

Because the laser L is incident from the top surface of the second adhesive layer 630 in the −z direction, an upper portion of the second adhesive layer 630 (or a part in a +z direction) may be exposed to the laser L for a longer time than a lower portion (or a part in the −z direction). Accordingly, a width of the hole 630-H of the second adhesive layer 630 may be greater in the upper portion (or the part in the +z direction) than in the lower portion (or the part in the −z direction). In other words, in a current step of the process, the hole 630-H of the second adhesive layer 630 may have a shape whose width decreases along the −z direction.

The first adhesive layer 610 may include a material having the same transmittance as the second adhesive layer 630. Accordingly, in a current step in which the laser L passes through the impact absorbing layer 620 and just enters the first adhesive layer 610, the laser L may pass through the first adhesive layer 610.

The laser L may pass through the bubble layer AB.

Referring to FIG. 5E, the laser L passing through the first adhesive layer 610 may cut the third touch insulating layer 450.

Because a sufficient time has passed since the laser L passes through the second adhesive layer 630, the hole 630-H of the second adhesive layer 630 may be a through hole having a constant width, like the hole 620-H in the impact absorbing layer 620.

Because a sufficient time has passed since the laser L was irradiated through the first adhesive layer 610, the first adhesive layer 610 may also be cut by heat of the laser L. Accordingly, a hole 610-H may begin to be formed in the first adhesive layer 610. The hole 610-H of the first adhesive layer 610 may also be a through hole.

Like the second adhesive layer 630, because the laser L is incident form a top surface of the first adhesive layer 610 in the −z direction, an upper portion of the first adhesive layer 610 (or a part in the +z direction) may be exposed to the laser L for a longer time than a lower portion (or a part in the −z direction). Accordingly, a width of the hole 610-H of the first adhesive layer 610 may be greater in the upper portion (or the part in the +z direction) than in the lower portion (or the part in the −z direction). In other words, in a current step of the process, the hole 610-H in the first adhesive layer 610 may have a shape whose width decreases along the −z direction.

The third touch insulating layer 450 may begin to be cut at the same time as the laser L is incident. Accordingly, a hole 450-H may be formed in the third touch insulating layer 450. The hole 450-H of the third touch insulating layer 450 may be a blind hole.

The particles of the fumes F generated during the cutting of the impact absorbing layer 620 may move in the −z direction along the hole 610-H of the first adhesive layer 610. For example, the particles of the fumes F may move in the −z direction (or gravity direction) along the hole 610-H of the first adhesive layer 610 due to the influence of gravity.

Some of the particles in the fumes F moving in the −z direction may scatter into the bubble layer AB. Others of the particles of the fumes F may move into the hole 450-H of the third touch insulating layer 450.

Referring to FIG. 5F, because a sufficient time has passed since the laser L passes through the first adhesive layer 610, the hole 610-H of the first adhesive layer 610 may be a through hole having a constant width, like the hole 620-H of the impact absorbing layer 620.

The laser L may passes through the third touch insulating layer 450. Accordingly, the hole 450-H of the third touch insulating layer 450 may be a through hole. Next, the laser L may continue to travel in the −z direction, to cut layers located under the third touch insulating layer 450 of FIG. 4 (or layers located in the −z direction).

The particles in the fumes F may move further in the −z direction. Compared to the step of FIG. 5E, the particles in the fumes F may move further in the −z direction, and more fume particles may scatter into the bubble layer AB.

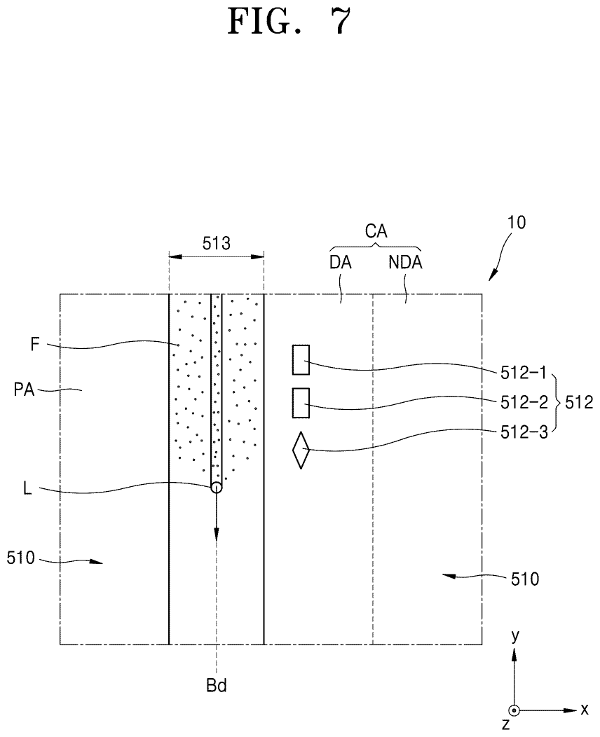

In this case, the fume particles scattering into the bubble layer AB may be collected in the bubble layer AB. Accordingly, when viewed in the +z direction, it is found that the fume particles are collected in the groove 513 where the bubble layer AB is located (see FIG. 7).

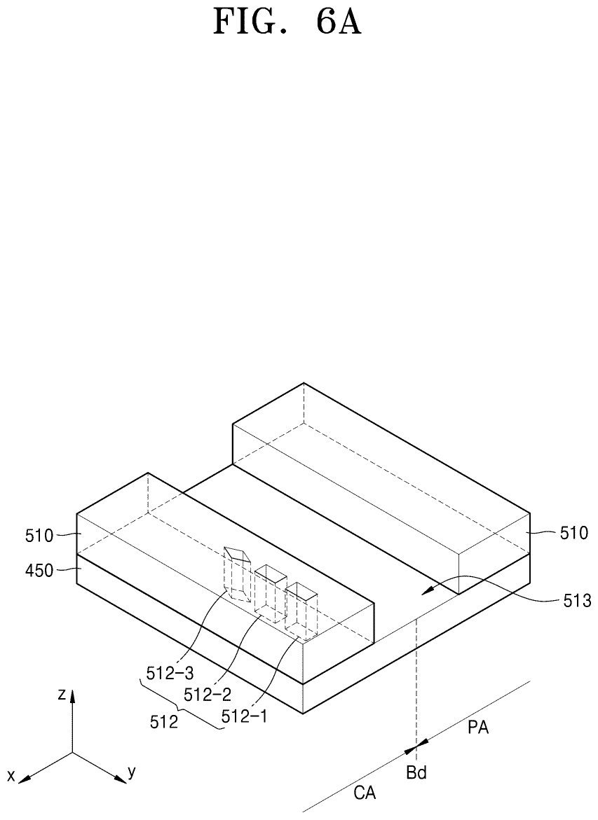

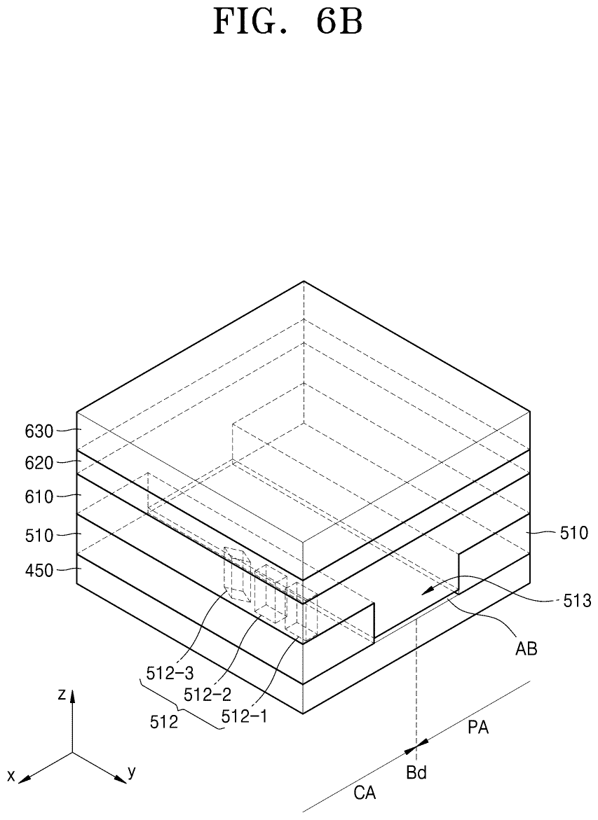

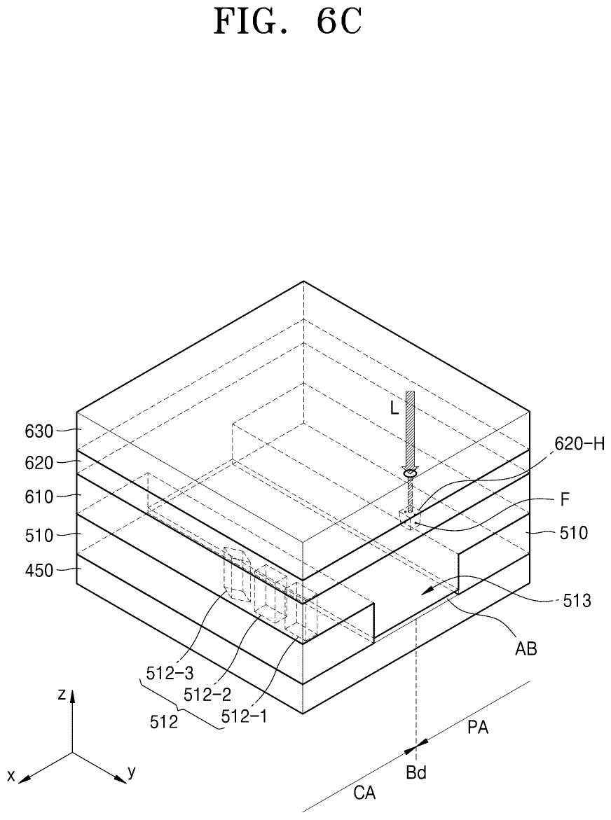

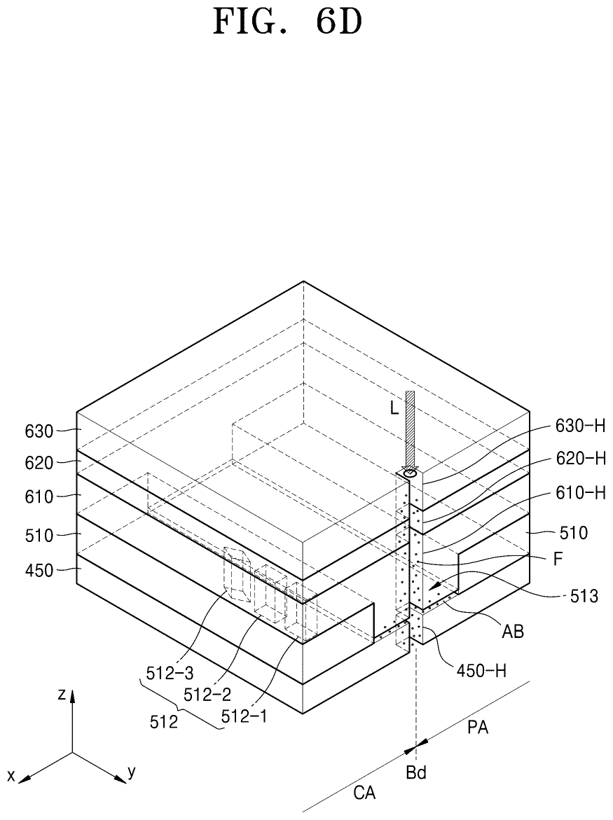

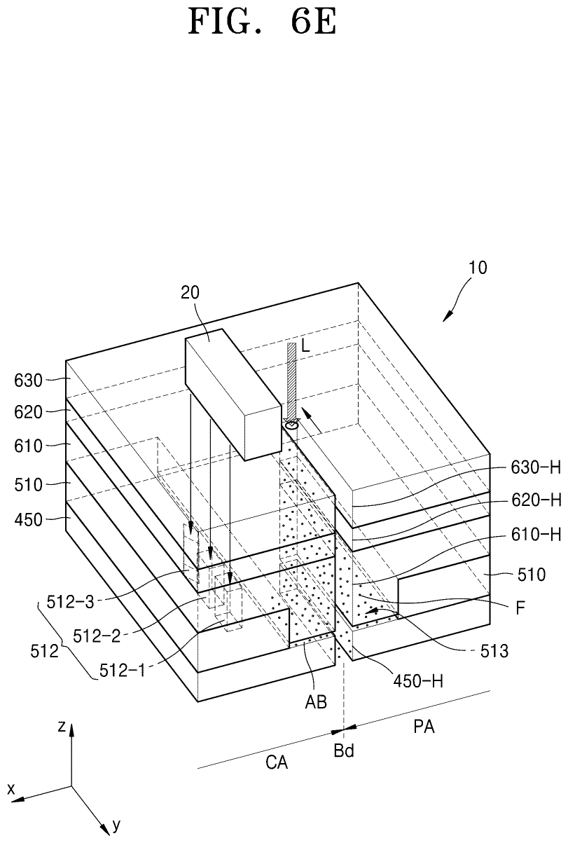

FIGS. 6A to 6E are perspective views illustrating states in process steps of a method of manufacturing a display apparatus according to an embodiment.

Although FIGS. 6A to 6E are illustrated with solid and dashed lines for convenience of illustration, it should be understood that an embodiment of FIGS. 6A to 6E does not refer to the entire display apparatus but is an enlarged view of a portion of a mother substrate of the display apparatus.

Referring to FIG. 6A, the light blocking layer 510 may be located on a touch layer, for example, the third touch insulating layer 450.

The light blocking layer 510 may include the groove 513 exposing the boundary Bd between the first area CA and the second area PA. In other words, a portion of the light blocking layer 510 may be located in the first area CA, and another portion may be located in the second area PA.

The groove 513 may be formed through the light blocking layer 510. Accordingly, a portion of the third touch insulating layer 450 may be exposed by the groove 513.

The light blocking layer 510 may include the second opening 512 located in the first area CA to be adjacent to the groove 513. The groove 513 and the second opening 512 may be disposed adjacent to each other and may be spaced apart from each other. The second opening 512 may include the 2-1 to 2-3 openings 512-1, 512-2, and 512-3 arranged along one direction (e.g., the ±y direction). A shape of one of the 2-1 to 2-3 openings 512-1, 512-2, and 512-3 may be different from that of the rest. For example, a shape of the 2-3 opening 512-3 may be different from shapes of the 2-1 and 2-2 openings 512-1 and 512-2.

The second opening 512 may be formed through the light blocking layer 510. Accordingly, a part of the third touch insulating layer 450 may be exposed through the second opening 512.

Referring to FIG. 6B, the first adhesive layer 610, the impact absorbing layer 620, and the second adhesive layer 630 may be sequentially formed on the light blocking layer 510.

A part of the first adhesive layer 610 may be located in the groove 513 of the light blocking layer 510. The first adhesive layer 610 may include a pressure sensitive adhesive. Accordingly, when the first adhesive layer 610 is located on the light blocking layer 510, due to viscosity of the first adhesive layer 610, the groove 513 of the light blocking layer 510 may not be completely filled. For example, the bubble layer AB may be formed under the first adhesive layer 610 in the groove 513.

The bubble layer AB may be located between the first adhesive layer 610 and the third touch insulating layer 450, and may be located in the groove 513 of the light blocking layer 510. In other words, the first adhesive layer 610 and the third touch insulating layer 450 may be spaced apart from each other in the groove 513 in the light blocking layer 510.

A portion of the first adhesive layer 610 may be located in the second opening 512 of the light blocking layer 510. For example, a portion of the first adhesive layer 610 may be located in the 2-1 to 2-3 openings 512-1, 512-2, and 512-3. Although not shown in the following drawings, like in the groove 513, a bubble layer may be located between the first adhesive layer 610 and the third touch insulating layer 450 in the second opening 512.

The first adhesive layer 610 may provide a flat surface on which the impact absorbing layer 620 may be located. The impact absorbing layer 620 and the second adhesive layer 630 may be sequentially located on the flat surface of the first adhesive layer 610.

FIG. 6C is a perspective view illustrating a step of the process of FIG. 5C.

Referring to FIG. 6C, the laser L may be incident from above the second adhesive layer 630 on a top surface of the second adhesive layer 630, or from one point in the +z direction of the second adhesive layer 630 in the −z direction.

The laser L may first pass through the second adhesive layer 630 including a material having a high transmittance.

Next, the laser L may be incident on the impact absorbing layer 620 to remove a part of the impact absorbing layer 620. Accordingly, the impact absorbing layer 620 may be removed earlier than the second adhesive layer 630.

The hole 620-H may be formed in the impact absorbing layer 620. Fumes F may be generated in a process in which the portion of the impact absorbing layer 620 is removed by the laser L. In a current step of the process, because there is no path through which particles of the fumes F may be discharged, the particles of the fumes F may be located in the hole 620-H of the impact absorbing layer 620.

Referring to FIG. 6D, corresponding holes may be respectively formed in the third touch insulating layer 450, the first adhesive layer 610, the impact absorbing layer 620, and the second adhesive layer 630.

FIG. 6D is a perspective view illustrating a step of the process of FIG. 5F after a step of the process of FIGS. 5D and 5E.

The hole 630-H may be formed in the second adhesive layer 630. The hole 620-H may be formed in the impact absorbing layer 620. The hole 610-H may be formed in the first adhesive layer 610. A hole may be formed in the third touch insulating layer 450. Although not shown in FIG. 6D, the hole may extend to a layer located under the third touch insulating layer 450. In an embodiment, the hole may extend to a bottom surface of the substrate 100 (see FIG. 4) to pass through the mother substrate of the display apparatus.

The fumes F generated from the impact absorbing layer 620 may move along the −z direction along the hole 620-H of the impact absorbing layer 620 and the hole 610-H of the first adhesive layer 610. For example, the particles of the fumes F may move in the −z direction due to the influence of gravity.

Some of the particles of the fumes F may be collected in the bubble layer AB. In other words, some of the particles of the fumes F may be located between the first adhesive layer 610 and the third touch insulating layer 450 and may be located in the groove 513 of the light blocking layer 510.

Others of the particles of the fumes F may move in the −z direction through the hole 450-H of the third touch insulating layer 450.

Referring to FIG. 6E, the mother substrate 10 of the display apparatus may be cut by moving the laser L along one path.

The laser L may move along the boundary Bd between the first area CA and the second area PA. In an embodiment, the laser L may move in the −y direction along the boundary Bd between the first area CA and the second area PA. Although the laser L linearly moves in FIG. 6E, the disclosure is not limited thereto. In another embodiment, in order to cut the mother substrate 10 of the display apparatus in a curved shape (e.g., in order to form a corner of the display apparatus), the laser L may move along a curved path.

The mother substrate 10 of the display apparatus may be cut along the path along which the laser L moves. For example, along the path along which the laser L moves, the hole 610-H of the first adhesive layer 610, the hole 620-H of the impact absorbing layer 620, the hole 630-H of the second adhesive layer 630, and the hole 450-H of the third touch insulating layer 450 may extend.

Holes of respective layers extending along the path of the laser L may be seen as portions cut by the laser L. Although not shown in FIG. 6E, a portion cut by the laser L may extend to a layer located under the third touch insulating layer 450. In an embodiment, the portion cut by the laser L may extend to a bottom surface of the substrate 100 (see FIG. 4) to pass through the mother substrate 10 of the display apparatus.

As the laser L moves, the impact absorbing layer 620 may be cut, and thus, the fumes F may be further generated. In this case, the particles of the fumes F may move in the −z direction along the hole 620-H of the impact absorbing layer 620 and the hole 610-H of the first adhesive layer 610 and may be collected in the bubble layer AB, like in FIG. 6D.

The second opening 512 may function as an alignment mark for determining whether the laser L moves along an intended path. In an embodiment, an inspection device 20 may be aligned with the second opening 512, and a cutting process may be performed by moving the laser L based on a position of the second opening 512 determined by the inspection device 20. Even during the cutting process, the inspection device 20 may guide the laser L by continuously determining the position of the second opening 512. The inspection device 20 may be located in the +z direction of the second opening 512.

In this case, when an upper end of the second opening 512 is covered, the inspection device 20 may not accurately recognize the position of the second opening 512, thereby causing an error in the path of the laser L. For example, when the fumes F generated from the impact absorbing layer 620 move to the second opening 512 and cover the second opening 512, the inspection device 20 may not accurately recognize the position of the second opening 512, thereby causing an error in the path of the laser L.

A structure of the mother substrate 10 of the display apparatus according to an embodiment may solve this problem. For example, the structure of the mother substrate 10 of the display apparatus may prevent the fumes F generated during the cutting of the impact absorbing layer 620 from moving to the upper end of the second opening 512, thereby preventing the second opening 512 from being covered by the fumes F.

The fumes F generated from the impact absorbing layer 620 may move along the hole 620-H of the impact absorbing layer 620 and the hole 610-H of the first adhesive layer 610, and then may be collected in the bubble layer AB.

The bubble layer AB may be located in the groove 513 of the light blocking layer 510, and may be spaced apart from the second opening 512. Because the second opening 512 and the groove 513 are spaced apart from each other, the fumes F may not move from the bubble layer AB located in the groove 513 to the second opening 512. Alternatively, the fumes F may not move to the second opening 512 by being blocked by a part of the light blocking layer 510 located between the second opening 512 and the groove 513. Accordingly, there is no path through which the fumes F may move to the upper end of the second opening 512.

Accordingly, the fumes F generated from the impact absorbing layer 620 may be prevented from covering the second opening 512.

FIG. 7 is a plan view illustrating states in process steps of a method of manufacturing a display apparatus according to an embodiment. FIG. 7 may be a plan view of an embodiment of FIG. 6E viewed in the +z direction.

Referring to FIG. 7, an embodiment of FIG. 7 may be a view viewed from the inspection device 20 (see FIG. 6E) of FIG. 6E.

The laser L may move along the boundary Bd between the first area CA and the second area PA to cut the mother substrate 10 of the display apparatus.

The second opening 512 may function as an alignment mark for guiding a movement direction of the laser L.

The particles of the fumes F may be collected in the groove 513 of the light blocking layer 510. The particles of the fumes F may not move beyond the groove 513 in the +x direction to cover the second opening 512.

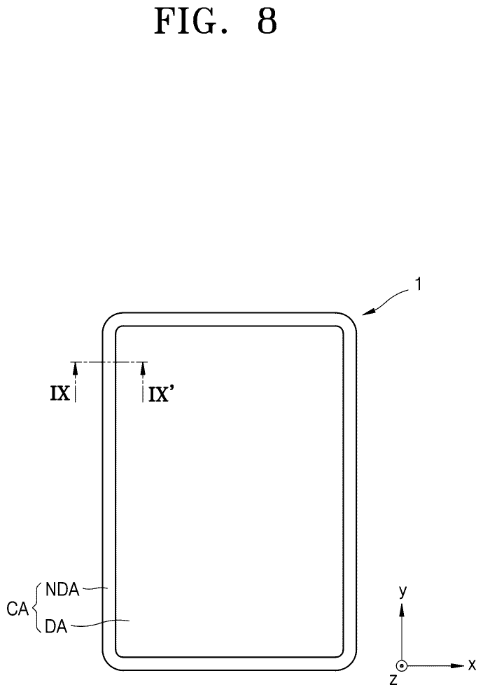

FIG. 8 is a plan view schematically illustrating a display apparatus manufactured by using a method of manufacturing a display apparatus according to an embodiment.

Referring to FIG. 8, the display apparatus 1 may be obtained by cutting (or scribing) the mother substrate 10 (see FIG. 1). After the cutting the mother substrate 10, the first areas CA may be the display apparatuses 1 and the remaining portions of the mother substrate 10 may be discarded.

The display apparatus 1 may include the display area DA and the non-display area NDA surrounding the display area DA.

A plurality of sub-pixels may be located in the display area DA to display an image. Each sub-pixel may include a light-emitting device such as an organic light-emitting diode.

The non-display area NDA is a portion where sub-pixels are not located, and a signal lines or a printed circuit board including a driving circuit and a power supply wiring for driving the sub-pixels may be located in the non-display area NDA.

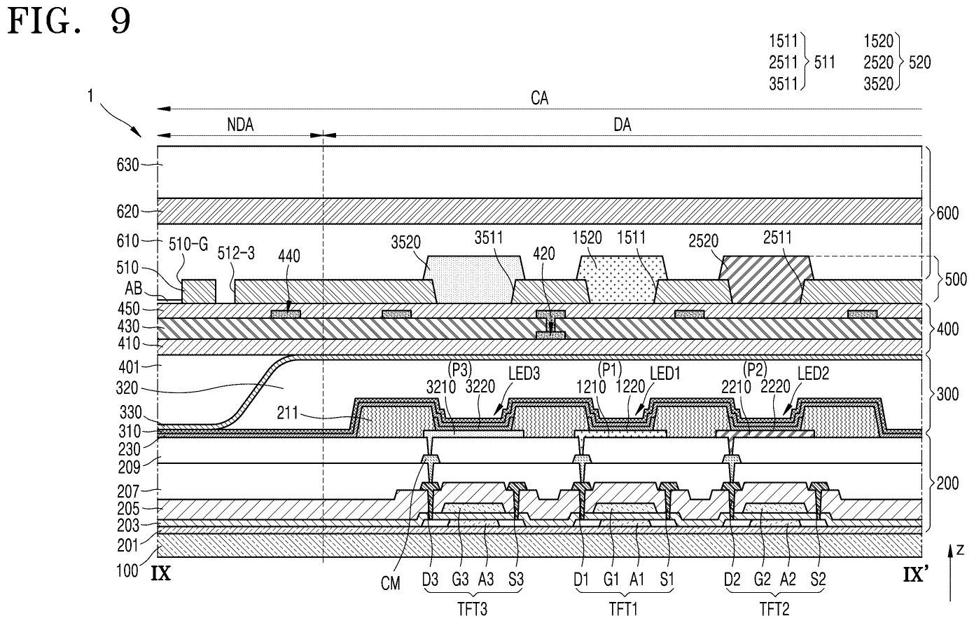

FIG. 9 is a cross-sectional view illustrating a portion of a display apparatus manufactured by using a method of manufacturing a display apparatus according to an embodiment.

Referring to FIG. 9, the display apparatus 1 may be obtained by cutting the mother substrate 10 (see FIG. 4) of the display apparatus of FIG. 4 along the boundary Bd (see FIG. 4) between the first area CA and the second area PA (see FIG. 4).

The cutting may be performed not only on the second adhesive layer 630, the impact absorbing layer 620, the first adhesive layer 610, and the third touch insulating layer 450 but also on lower layers disposed under the third touch insulating layer 450. For example, the cutting may also be performed on the touch layer 400, the encapsulation layer 300, the display layer 200, and the substrate 100.

The light blocking layer 510 may include a stepped portion 510-G located along an edge of the non-display area NDA. A portion of the light blocking layer 510 located in the second area PA (see FIG. 4) may be removed. Accordingly, a space where the groove 513 (see FIG. 4) of the light blocking layer 510 was located may no longer be in a groove shape but in a stepped shape between the light blocking layer 510 and the third touch insulating layer 450.

The second opening 512 may be located adjacent to the stepped portion 510-G. For example, the second opening 512 may be located between the stepped portion 510-G and the display area DA.

The first adhesive layer 610 and the third touch insulating layer 450 may be spaced apart from each other in the stepped portion 510-G of the light blocking layer 510. In an embodiment, the bubble layer AB may be located between the first adhesive layer 610 and the third touch insulating layer 450 in the stepped portion 510-G of the light blocking layer 510. In another embodiment, after the cutting process, the bubble layer AB may be removed and sealed, and a space between the first adhesive layer 610 and the third touch insulating layer 450 may be in a vacuum state.

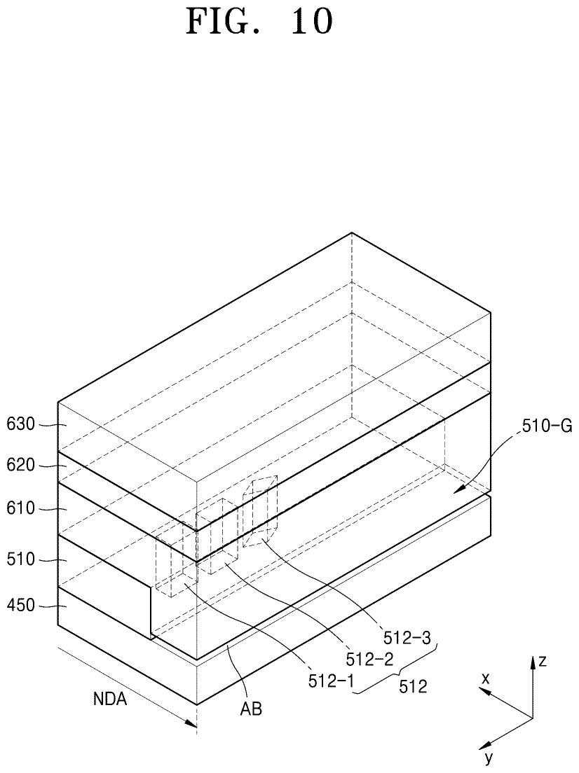

FIG. 10 is an enlarged perspective view illustrating a portion of a display apparatus manufactured by using a method of manufacturing a display apparatus according to an embodiment.

An embodiment of FIG. 10 may be obtained by removing the second area PA (see FIG. 6A) after a cutting process is completed according to an embodiment of FIG. 6E.

Although FIG. 10 is illustrated with solid and dashed lines for convenience of illustration, it should be understood that the embodiment of FIG. 10 does not refer to the entire display apparatus but is an enlarged view of a portion of the display apparatus.

Referring to FIG. 10, the light blocking layer 510 may include the stepped portion 510-G located at an edge of the non-display area NDA.

The first adhesive layer 610 may be located on the light blocking layer 510 while covering an edge of the light blocking layer 510. A portion of the first adhesive layer 610 may be located on the stepped portion 510-G of the light blocking layer 510. A portion of a side surface of the light blocking layer 510 facing the stepped portion 510-G (e.g., a side surface of the light blocking layer 510 facing the −x direction)may be covered by the first adhesive layer 610.

In the stepped portion 510-G, the first adhesive layer 610 and the third touch insulating layer 450 may not be directly contacted each other but may be spaced apart from each other. In an embodiment, the bubble layer AB may be located between the first adhesive layer 610 and the third touch insulating layer 450 in the stepped portion 510-G. In another embodiment, in the stepped portion 510-G, a space located between the first adhesive layer 610 and the third touch insulating layer 450 may be in a vacuum state.

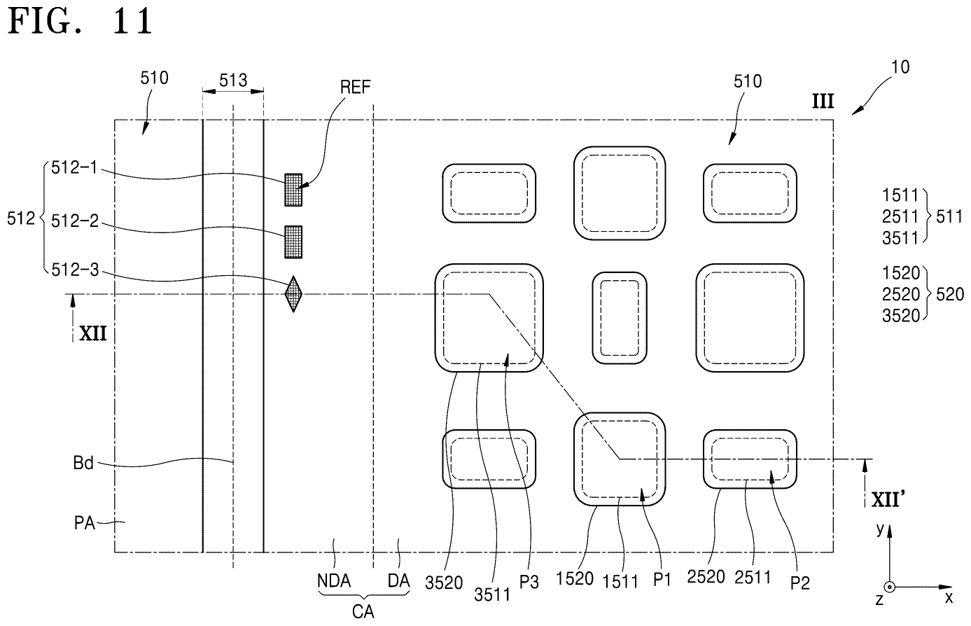

FIG. 11 is an enlarged plan view illustrating a portion of a mother substrate of a display apparatus, particularly illustrating the portion III of FIG. 1, according to an embodiment.

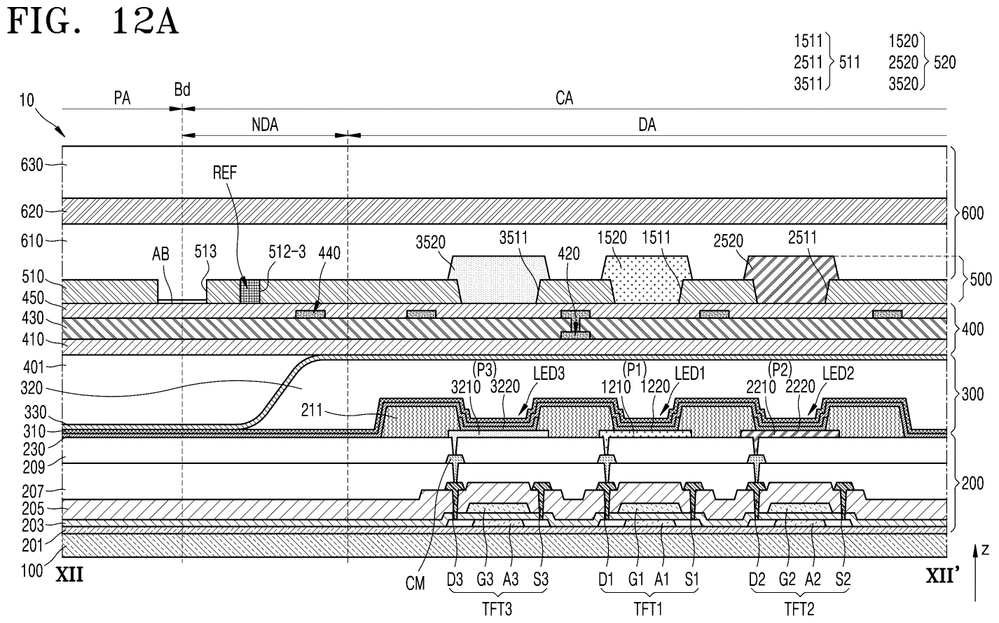

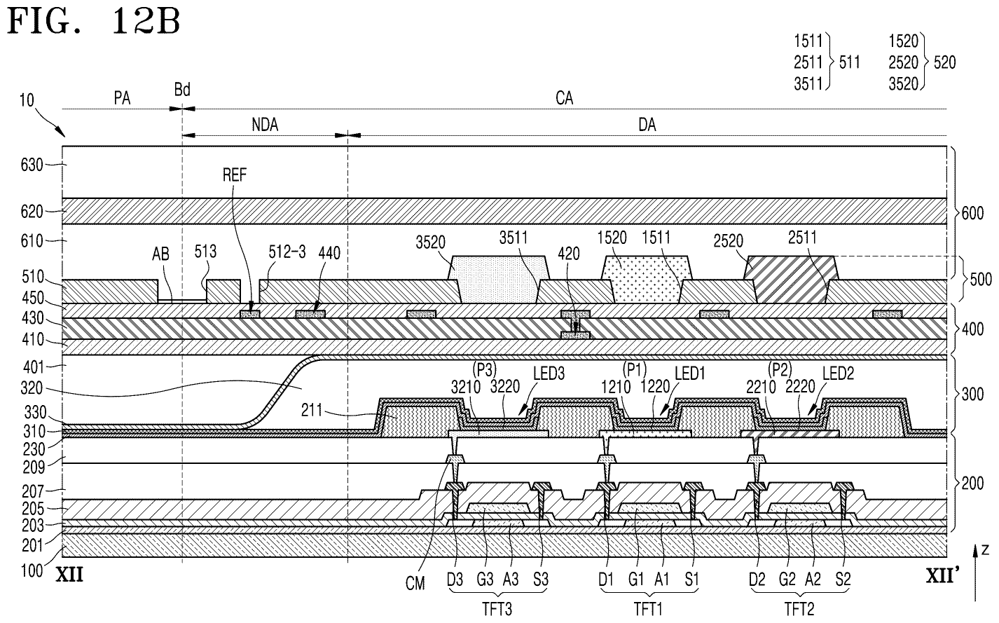

FIG. 12A is a cross-sectional view illustrating a portion of a mother substrate of a display apparatus, taken along line XII-XII′ of FIG. 11, according to an embodiment.

FIG. 12B is a cross-sectional view illustrating a portion of a mother substrate of a display apparatus, taken along line XII-XII′ of FIG. 11, according to another embodiment.

Referring to FIGS. 11 and 12A together, a reflective pattern REF may be located in the second opening 512. In an embodiment, the reflective pattern REF may be located in at least one of the 2-1 opening 512-1, the 2-2 opening 512-2, and the 2-3 opening 512-3. In an embodiment, the reflective pattern REF may be located in all of the 2-1 opening 512-1, the 2-2 opening 512-2, and the 2-3 opening 512-3.

In an embodiment, the reflective pattern REF may completely fill the second opening 512. For example, as shown in FIG. 12A, the reflective pattern REF may completely fill the 2-3 opening 512-3. In an embodiment, a top surface of the reflective pattern REF and a top surface of the light blocking layer 510 may be flat. In other words, the top surface of the reflective pattern REF and the top surface of the light blocking layer 510 may be located on the same plane. In another embodiment, unlike in FIG. 12A, the top surface of the reflective pattern REF may protrude or be recessed from the top surface of the light blocking layer 510.

In an embodiment, the reflective pattern REF may include a material capable of reflecting light. In an embodiment, the reflective pattern REF may include a metal. In an embodiment, the reflective pattern REF may include a metal such as titanium (Ti), aluminum (Al), silver (Ag), or molybdenum (Mo).

Referring to FIGS. 11 and 12B, the reflective pattern REF may not be located in the second opening 512, but may instead be located on another layer to overlap the second opening 512 in a plan view. For example, as shown in FIG. 12B, the reflective pattern REF may be located on the same layer as the second conductive layer 440. In an embodiment, the reflective pattern REF and the second conductive pattern 440 may be simultaneously formed. In another embodiment, the reflective pattern REF may be located on the same layer as the first conductive pattern 420. In this case, the reflective pattern REF and the first conductive pattern 420 may be simultaneously formed. As such, the reflective pattern REF may be located on any of various layers while overlapping the second opening 512 in a plan view to be recognized by the inspection device 20 (see FIG. 6E).

The following will be described assuming that the reflective pattern REF is located in the second opening 512 as shown in FIG. 12A for convenience of explanation. Accordingly, it should be understood that the disclosure is not limited to a case where the reflective pattern REF is located in the second opening 512 and the reflective pattern REF may be located on any layer while overlapping the second opening 512 in a plan view.

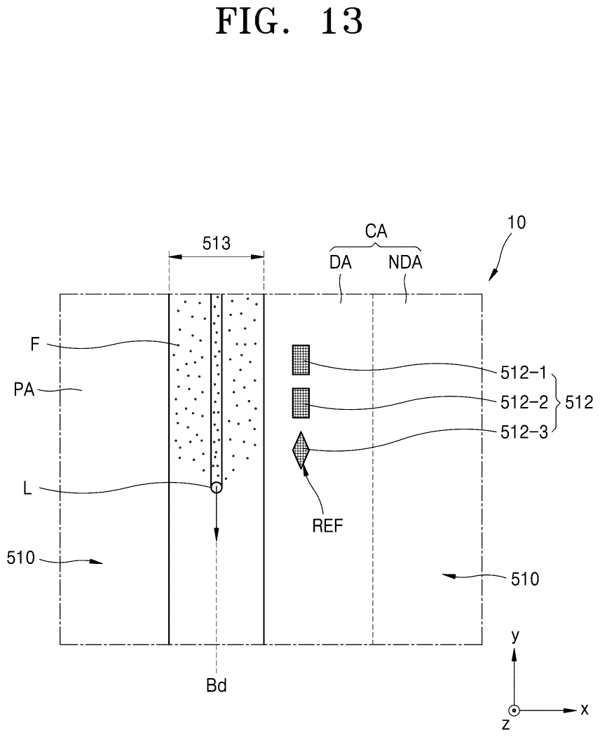

FIG. 13 is a plan view illustrating states in process steps of a method of manufacturing a display apparatus according to an embodiment.

Referring to FIGS. 6A to 6E, 7, and 13 together, like in FIGS. 11 and 12, the reflective pattern REF may be located in the second opening 512. Accordingly, the reflective pattern REF may be located even in the second opening 512 of an embodiment of FIGS. 6A to 6E and 7. For example, the reflective pattern REF may be located in the 2-1 opening 512-1, the 2-2 opening 512-2, and the 2-3 opening 512-3. A plan view of an embodiment in which the reflective pattern REF is located in the second opening 512 is illustrated in FIG. 13.

In this case, the reflective pattern REF may function as an alignment mark for guiding a movement direction of a laser L. For example, referring to FIGS. 6E, 7, and 13 together, the inspection device 20 may be aligned with the reflective pattern REF, and a cutting process may be performed by moving the laser L based on a position of the reflective pattern REF determined by the inspection device 20. Even during the cutting process, the inspection device 20 may guide the laser L by continuously determining the position of the reflective pattern REF. In an embodiment, the inspection device 20 may irradiate light toward the reflective pattern REF and may determine the position of the reflective pattern REF by recognizing light reflected from the reflective pattern REF.

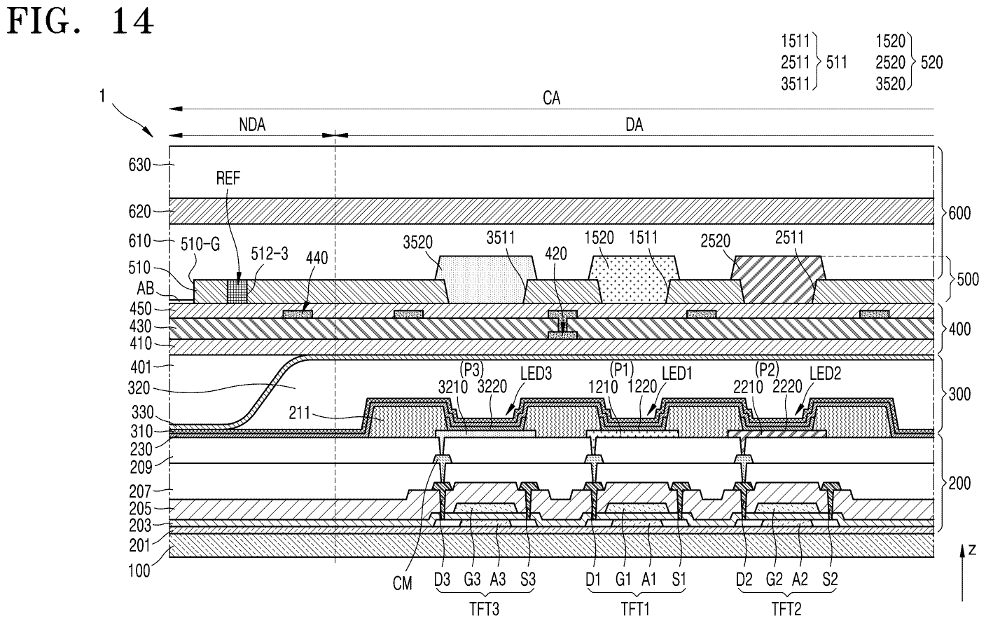

FIG. 14 is a cross-sectional view illustrating a part of a display apparatus according to an embodiment.

Referring to FIG. 14, the display apparatus 1 may be obtained by cutting the mother substrate 10 (see FIG. 12) illustrated in FIG. 12 along the boundary Bd (see FIG. 12) between the first area CA and the second area PA (see FIG. 12).

Accordingly, the display apparatus 1 may include the reflective pattern REF located in the second opening 512 (see FIG. 11), for example, the 2-3 opening 512-3.

It will be understood by one of ordinary skill in the art that the display apparatus may be manufactured by similarly cutting the mother substrate 10 (see FIG. 12A) of the display apparatus illustrated in FIG. 12A.

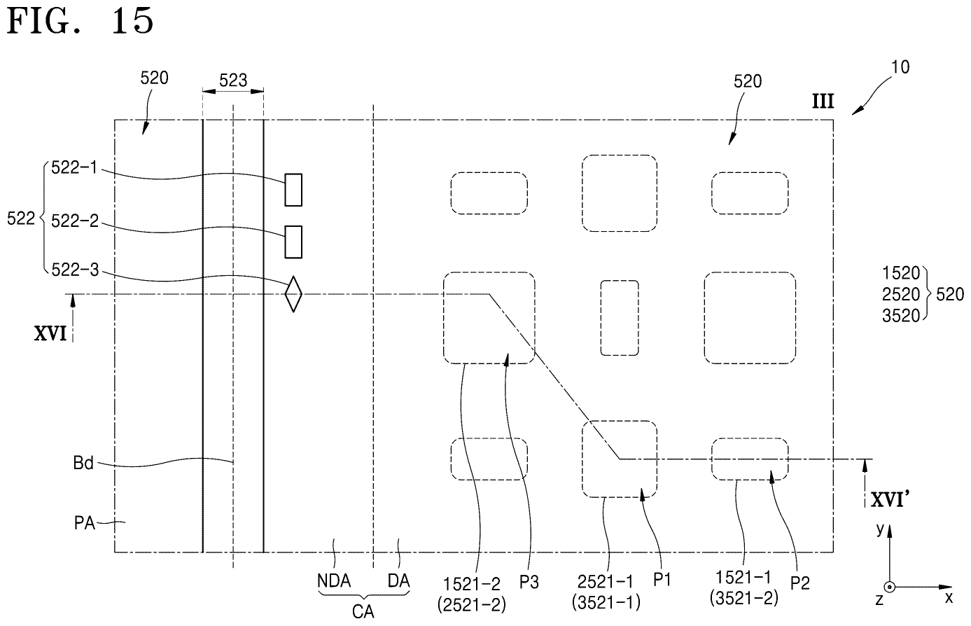

FIG. 15 is an enlarged plan view illustrating a portion of a mother substrate of a display apparatus, particularly illustrating the portion III of FIG. 1, according to an embodiment.

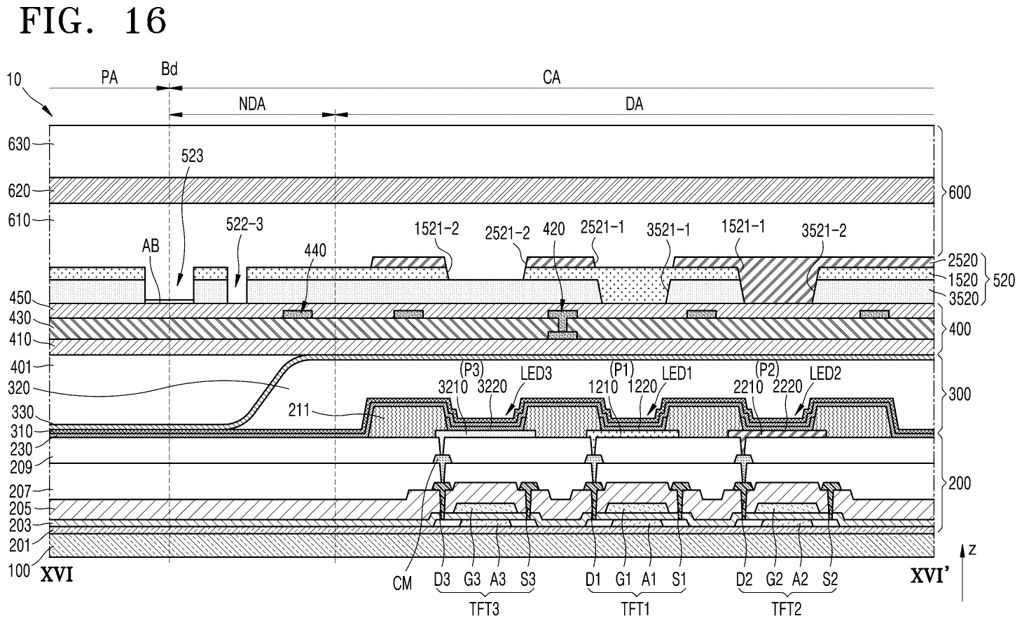

FIG. 16 is a cross-sectional view illustrating a portion of a mother substrate of a display apparatus, taken along line XVI-XVI′ of FIG. 15, according to an embodiment.

Referring to FIGS. 15 and 16 together, the mother substrate 10 of the display apparatus may not include a light blocking layer. Instead, the stacked color filters 520 may be located on the touch layer 400. For example, the first color filter 1520, the second color filter 2520, and the third color filter 3520 may be located on the third touch insulating layer 450. In an embodiment, the third color filter 3520 may be located on a top surface of the third touch insulating layer 450. In an embodiment, the first color filter 1520 may be located on the third color filter 3520. In an embodiment, the second color filter 2520 may be located on the first color filter 1520.

Each color filter may include openings disposed in areas corresponding to sub-pixels other than a corresponding sub-pixel.

The first color filter 1520 may include openings in areas corresponding to a second sub-pixel P2 and a third sub-pixel P3. In an embodiment, the first color filter 1520 may include a 1-1 opening 1521-1 in an area corresponding to the second sub-pixel P2. In an embodiment, the first color filter 1520 may include a 1-2 opening 1521-2 in an area corresponding to the third sub-pixel P3.

The second color filter 2520 may include openings in areas corresponding to the first sub-pixel P1 and the third sub-pixel P3. In an embodiment, the second color filter 2520 may include a 1-3 opening 2521-1 in an area corresponding to the first sub-pixel P1. In an embodiment, the second color filter 2520 may include a 1-4 opening 2521-2 in an area corresponding to the third sub-pixel P3.

The third color filter 3520 may include openings in areas corresponding to the first sub-pixel P1 and the second sub-pixel P2. In an embodiment, the third color filter 3520 may include a 1-5 opening 3521-1 in an area corresponding to the first sub-pixel P1. In an embodiment, the third color filter 3520 may include a 1-6 opening 3521-2 in an area corresponding to the second sub-pixel P2.

In an embodiment, the 1-1 opening 1521-1 of the first color filter 1520 and the 1-6 opening 3521-2 of the third color filter 3520 may be disposed in a same area. In an embodiment, the 1-2 opening 1521-2 of the first color filter 1520 and the 1-4 opening 2521-2 of the second color filter 2520 may be disposed in a same area. In an embodiment, the 1-3 opening 2521-1 of the second color filter 2520 and the 1-5 opening 3521-1 of the third color filter may be disposed in a same area.

In an embodiment, a portion of the first color filter 1520 may fill the 1-5 opening 3521-1 of the third color filter 3520. In an embodiment, a portion of the second color filter 2520 may fill the 1-1 opening 1521-1 of the first color filter 1520 and the 1-6 opening 3521-2 of the third color filter 3520.

In an embodiment, the first sub-pixel P1 may emit red light. In an embodiment, the second sub-pixel P2 may emit green light. In an embodiment, the third sub-pixel P3 may emit blue light.

In an embodiment, the first color filter 1520 may transmit red light. In an embodiment, the second color filter 2520 may transmit green light. In an embodiment, the third color filter 3520 may transmit blue light.

In an embodiment, light emitted from the first sub-pixel P1 (e.g., red light) may pass through the 1-5 opening 3521-1 of the third color filter 3520 while being transmitted through the first color filter 1520, and then may pass through the 1-3 opening 2521-1 of the second color filter 2520.

In an embodiment, light emitted from the second sub-pixel P2 (e.g., green light) may pass through the 1-1 opening 1521-1 of the first color filter 1520 and the 1-6 opening 3521-2 of the third color filter 3520 while being transmitted through the second color filter 2520.

In an embodiment, light emitted from the third sub-pixel P3 (e.g., blue light) may be transmitted through the third color filter 3520, and then may pass through the 1-2 opening 1521-2 of the first color filter 1520 and then may pass the 1-4 opening 2521-2 of the second color filter 2520.

In a region where two or more of color filters overlap each other, the overlapping color filters may perform a function similar to that of the light blocking layer 510 (see FIG. 4). Color filters may transmit light of different colors. When two or more color filters overlap each other, light transmitted through one color filter may not pass through another color filter. Accordingly, when color filters overlap each other, no light may pass through the overlapping color filters. Accordingly, a region where color filters overlap each other is visible as black to a user and, thus, may perform a function similar to that of the light blocking layer 510 (see FIG. 4).

In an embodiment, the color filters 520 may overlap each other in a region between sub-pixels in the display area DA. For example, in a region overlapping the sub-pixel-defining layer 211, the first color filter 1520, the second color filter 2520, and the third color filter 3520 may overlap each other. In an embodiment, in a region overlapping the sub-pixel-defining layer 211, the first color filter 1520 and the second color filter 2520 may be sequentially located on the third color filter 3520 to overlap each other. The region where the first color filter 1520, the second color filter 2520, and the third color filter 3520 overlap each other may be visible as black to the user. Accordingly, the first conductive layer 420 and the second conductive layer 440 of the touch layer 400 may be covered and may not be visible to the user.

In an embodiment, some color filters may extend beyond the display area DA to the non-display area NDA. In an embodiment, some color filters may extend beyond the boundary Bd between the first area CA and the second area PA to the second area PA. In an embodiment, the first color filter 1520 and the third color filter 3520 may extend to the non-display area NDA and the second area PA. In other words, the first color filter 1520 and the third color filter 3520 may be located in both the first area CA and the second area PA. The first color filter 1520 and the third color filter 3520 may be visible as black in the non-display area NDA and the second area PA. Accordingly, an overlapping structure of the first color filter 1520 and the third color filter 3520 may also perform a function similar to that of the light blocking layer 510 (see FIG. 4).

In other words, referring to FIG. 2 together, the mother substrate 10 of the display apparatus of an embodiment illustrated in FIGS. 15 and 16 may include the optical functional layer 500. The optical functional layer 500 of the present embodiment may include the color filters 520 and may not include a light blocking layer. Also, the optical functional layer 500 of the present embodiment may include a light transmitting portion and a light blocking portion.

In the present embodiment, only one color filter may be disposed in each of the light transmitting portion of the optical functional layer 500 and at least two color filters may be disposed in the light blocking portion. For example, a portion of the third color filter 3520 are disposed in the 1-2 opening 1521-2 and the 1-4 opening 2521-2. In another embodiment, a portion of the first color filter 1520 may be disposed in the 1-3 opening 2521-1 and the 1-5 opening 3521-1. In another embodiment, a portion of the second color filter 2520 may be disposed in the 1-1 opening 1521-1 and the 1-6 opening 3521-2.

In the present embodiment, the light blocking portion of the optical function layer 500 may include a portion where the color filters 520 overlap each other. For example, a portion where the color filters 520 overlap each other in a region between sub-pixels in the display area DA may be included in the light blocking portion of the optical functional layer 500. In another embodiment, a portion where the first color filter 1520 and the third color filter 3520 overlap each other in the non-display area NDA and the second area PA may be included in the light blocking portion of the optical functional layer 500.

The color filters 520 may include an alignment mark, for example, a second opening 522, located in the non-display area NDA. The second opening 522 of the color filter 520 may include a 2-1 opening 522-1, a 2-2 opening 522-2, and a 2-3 opening 522-3 aligned along one axis (e.g., a y axis). The second opening 522 of the color filter 520 may be formed through the first color filter 1520 and the third color filter 3520. The second opening 522 of the color filter 520 may formed through the first color filter 1520 and the third color filter 3520. The second opening 522 of the color filter 520 and the second opening 512 (see FIG. 3) of the light blocking layer 510 (see FIG. 3) may have similar characteristics.

The color filters 520 may include a groove 523 disposed in an area corresponding to the boundary Bd between the first area CA and the second area PA. The groove 523 of the color filter 520 may extend along one axis (e.g., the y axis). The groove 523 of the color filter 520 may be formed in the first color filter 1520 and the third color filter 3520. The groove 523 of the color filter 520 may be formed through the first color filter 1520 and the third color filter 3520. The groove 523 of the color filter 520 and the groove 513 (see FIG. 3) of the light blocking layer 510 (see FIG. 3) may have similar characteristics.

The first adhesive layer 610, the impact absorbing layer 620, and the second adhesive layer 630 may be sequentially located on the color filters 520. A part of the first adhesive layer 610 may be located in the groove 523 of the color filter 520. The bubble layer AB may be located between the portion of the first adhesive layer 610 located in the groove 523 of the color filter 520 and a top surface of the third touch insulating layer 450.

Although not shown in FIGS. 15 and 16, in an embodiment, the reflective pattern REF (see FIG. 11) overlapping the second opening 522 of the color filter 520 may be located.

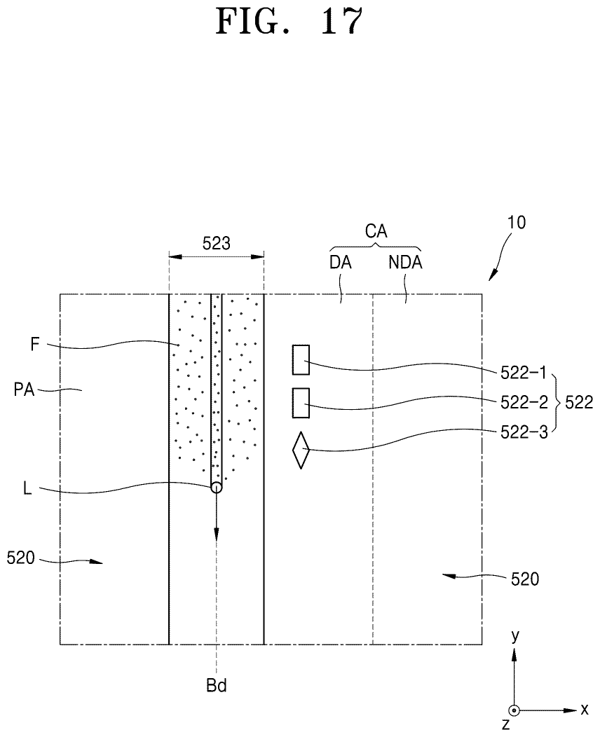

FIG. 17 is a plan view illustrating states in process steps of a method of manufacturing a display apparatus according to an embodiment.

Referring to FIGS. 7 and 17 together, the color filter 520 of FIG. 17 may perform a function similar to that of the light blocking layer 510 of FIG. 7.

The second opening 522 of the color filter 520 of FIG. 17 may perform a function similar to that of the second opening 512 of the light blocking layer 510 of FIG. 7. In an embodiment, the laser L may move along the boundary Bd between the first area CA and the second area PA to cut the mother substrate 10 of the display apparatus, and, in this case, the second opening 522 of the color filter 520 may function as an alignment mark for guiding a movement direction of the laser L.

The groove 523 of the color filter 520 of FIG. 17 may perform a function similar to that of the groove 513 of the light blocking layer 510 of FIG. 7. In an embodiment, particles of fume (F) may be collected in the groove 523 of the color filter 520. The particles of the fume F may not move beyond the groove 523 of the color filter 520 in the +x direction, and thus, the second opening 522 of the color filter 520 may not be covered by the particles of fume F.

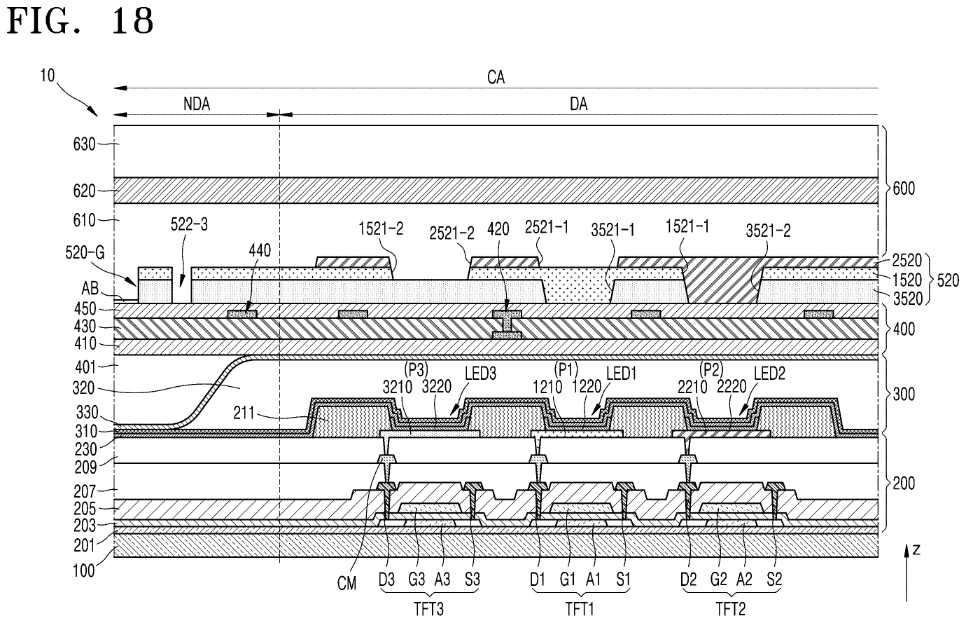

FIG. 18 is a cross-sectional view illustrating a part of a display apparatus according to an embodiment.

Referring to FIG. 18, the display apparatus 1 may be obtained by cutting the mother substrate 10 (see FIG. 16) illustrated in FIG. 16 along the boundary Bd (see FIG. 16) between the first area CA and the second area PA (see FIG. 16).

Referring to FIGS. 8 and 18 together, like the stepped portion 510-G of FIG. 8, the color filter 520 may include a stepped portion 520-G located at an edge of the non-display area NDA. A portion of the color filter 520 located in the second area PA (see FIG. 16) may be removed. Accordingly, a space where the groove 523 (see FIG. 16) of the color filter 520 was located may no longer be in a groove shape but in a stepped shape. For example, the space may have a stepped shape between the first color filter 1520, the third color filter 3520, and the third touch insulating layer 450.

A portion of the first adhesive layer 610 may be located in the stepped portion 520-G of the color filter 520. In this case, the part of the first adhesive layer 610 and a top surface of the touch layer 400 (e.g., a top surface of the third touch insulating layer 450) may not directly contact each other by may be spaced apart from each other. The bubble layer AB may be located between the part of the first adhesive layer 610 and the top surface of the touch layer 400 (e.g., the top surface of the third touch insulating layer 450).

Although not shown in FIGS. 17 and 18, in an embodiment, the reflective pattern REF (see FIG. 11) overlapping the second opening 522 of the color filter 520 may be located.

According to an embodiment, as described above, there may be provided a display apparatus in which fumes are located in a groove formed in a light blocking layer and an alignment mark is formed at a position spaced apart from the groove so that the alignment mark is not covered by the particles of fumes, and a method of manufacturing the display apparatus. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A method of manufacturing a display apparatus, the method comprising:
preparing a substrate comprising a first area in which a display layer comprising a plurality of light-emitting devices is located and a second area surrounding the first area; and
forming an optical functional layer on the display layer, the optical functional layer comprising:
a light transmitting portion at least partially overlapping the plurality of light-emitting devices,
a light blocking portion at least partially surrounding the light transmitting portion,
an alignment mark formed through the light blocking portion, the alignment mark being disposed adjacent to a boundary between the first area and the second area, and
a groove extending along the boundary between the first area and the second area.

2. The method of claim 1, wherein the light blocking portion of the optical functional layer comprises a light blocking layer, and
wherein the light transmitting portion of the optical functional layer comprises a plurality of color filters located in a plurality of openings formed through the light blocking layer.

3. The method of claim 1, wherein the optical functional layer comprises a plurality of color filters which transmit light of different colors, and
wherein the light blocking portion comprises at least two of the plurality of color filters overlapping each other.

4. The method of claim 1, wherein the alignment mark comprises a plurality of openings spaced apart from each other along one direction,
wherein a shape of one of the plurality of openings is different from a shape of another one of the plurality of openings in a plan view.

5. The method of claim 4, wherein the plurality of openings of the alignment mark are formed through the optical functional layer.

6. The method of claim 4, further comprising forming a reflective pattern at least partially overlapping the alignment mark.

7. The method of claim 1, further comprising:
sequentially locating a first adhesive layer, an impact absorbing layer, and a second adhesive layer on the optical functional layer; and
cutting the second adhesive layer, the impact absorbing layer, the first adhesive layer, the display layer, and the substrate along a scribe line disposed adjacent to the alignment mark of the optical functional layer.

8. The method of claim 7, wherein a portion of the first adhesive layer is located in the groove of the optical functional layer not to directly contact a layer disposed under the optical functional layer.

9. The method of claim 7, wherein, in the cutting, the scribe line is disposed at the boundary between the first area and the second area.

10. The method of claim 7, wherein a laser is sequentially incident on the second adhesive layer, the impact absorbing layer, the first adhesive layer, the display layer, and the substrate.

11. The method of claim 7, wherein the impact absorbing layer is cut earlier than the second adhesive layer and the first adhesive layer during the cutting.

12. The method of claim 7, wherein at least part of particles in fume generated during the cutting of the impact absorbing layer moves to the groove of the optical functional layer.

13. A display apparatus comprising:
a substrate comprising a display area in which a plurality of light-emitting devices are located and a non-display area surrounding the display area; and
an optical functional layer located on the substrate, the optical functional layer comprising:
a light transmitting portion at least partially overlapping the plurality of light-emitting devices,
a light blocking portion at least partially surrounding the light transmitting portion,
a stepped portion located at an edge of the non-display area, and
an alignment mark located in the non-display area adjacent to the stepped portion.

14. The display apparatus of claim 13, wherein the light blocking portion of the optical functional layer comprises a light blocking layer, and
wherein the light transmitting portion of the optical functional layer comprises a plurality of color filters located in a plurality of openings formed through the light blocking layer.

15. The display apparatus of claim 13, wherein the optical functional layer comprises a plurality of color filters which transmit light of different colors, and
wherein the light blocking portion comprises at least two of the plurality of color filters overlapping each other.

16. The display apparatus of claim 13, wherein the alignment mark comprises a plurality of openings located in the light blocking portion to be spaced apart from each other along one direction,
wherein a shape of one of the plurality of openings is different from a shape of another one of the plurality of openings in a plan view.

17. The display apparatus of claim 16, wherein the plurality of openings of the alignment mark are formed through the optical functional layer.

18. The display apparatus of claim 16, further comprising a reflective pattern at least partially overlapping the alignment mark.

19. The display apparatus of claim 13, further comprising a first adhesive layer located on the optical functional layer while covering an edge of the optical functional layer disposed adjacent to the stepped portion, a part of the first adhesive layer being located to cover the stepped portion.

20. The display apparatus of claim 19, further comprising a touch layer disposed between the substrate and the optical functional layer,
wherein the first adhesive layer and the touch layer do not directly contact each other in the stepped portion.
